(19) United States
(12) Patent Application Publication
(10) Pub. No.: US 2011/0251071 A1
(43) Pub. Date: Oct. 13, 2011

(54) Method of Realization of Hyperconductivity and Super Thermal Conductivity

(76) Inventor: Vyacheslav Andreevich Vdovenkov, Moscow (RU)

(21) Appl. No.: 13/140,038

(22) PCT Filed: May 26, 2009
(86) PCT No.: PCT/IB09/05723

§ 371 Date: Jun. 16, 2011

(51) Int. Cl. H01L 39/22

(52) U.S. Cl. 505/191; 257/471; 257/E27.007

(57) ABSTRACT

The application relates to electricity, electro-physics and thermo conductivity of materials, to the phenomena of zero electric resistance, i.e. to hyperconductivity (superconductivity) and zero thermal resistance, i.e. to superthermoconductivity of materials at near-room and higher temperatures. The matter: on the surface of in the volume of non-degenerate or poorly degenerate semiconductor material or layer of such material on semi-insulating or dielectric substrate the electrodes are located forming rectifying contacts to the material. The distance between the electrodes (D) is chosen much smaller comparing to the depth of penetration into the material of the electric field caused by their contact difference of potentials (L), (D<<L) Minimum distance between the electrodes D_{MIN}=20 nanometers, maximum distance between the electrodes D_{MAX}=30 micrometers. Before, after or during forming of the gap having width D between the electrodes, electron-vibration centers (EVCs) are inputted into the material having concentration (N) from 2-10¹² cm⁻³ to 6-10¹⁷ cm⁻³. Temperature of the material is brought to the temperature of hyperconductivity transition (Tₕ) or higher. The technical result: possibility to achieve the said effect of hyperconductivity (superconductivity) and zero thermal resistance, i.e. to superthermoconductivity at the temperatures above Tₕ and possibility to adjust the value of Tₕ.

Pertinent arts. The invention relates to electricity, electro-physics and thermal conductivity of materials, to the phenomenon of zero electric resistance, i.e. to hyperconductivity, as well as to the phenomena of zero thermal resistance, i.e. to superthermoconductivity of materials at near-room and higher temperatures.

The invention may be used in nanoelectronics, microelectronics, radio engineering and electrical engineering, transport systems.

The invention realizes a new physical mechanism of forming zero electric resistance of materials and zero thermal resistance of materials, i.e. hyperconductivity and super thermal conductivity, at near-room and higher temperatures.

Hyperconductivity is the state of a material having zero electric resistance. This state—state of hyperconductivity—appears and exists in semiconductor materials containing electron-vibration centers (EVCs) between electrodes at the temperature of the hyperconductivity transition (Tₕ) and higher temperatures. The materials between the electrodes, where hyperconductivity exists when they are heated above the temperature Tₕ, are the hyperconductors or hyperconductive materials.

Super thermal conductivity, or superthermoconductivity, is the state of the material having zero thermal resistance. This state, the state of superthermoconductivity, or superthermoconductive state, appears and exists in semiconductor materials containing electron-vibration centers (EVCs) between electrodes at the temperature of hyperconductivity transition Tₕ and higher temperatures.

Hyperconductivity and superthermoconductivity are the mutually bound states of materials and cannot be realized separately from each other. This is defined by the fact that after electron-vibration centers have been inputted into the material, electrons and phonons become strongly bound to each other and to EVCs at temperatures above Tₕ. As the result, electrons and phonons are making transitions together—electron-vibration transitions from one EVC to another EVC, under the conditions of gradient of EVCs concentration or under influence of gradient of electric potential, electric field or temperature gradient. These electron-vibration transitions are the quantum transitions, they happen without spending energy, and thanking to this the electric and thermal resistances of the material between the electrodes turn into zero, and by this hyperconductivity and superthermoconductivity are realized.

Phenomenon of materials turning into the hyperconductive state arises when heating the material up to Tₕ, and this represents the phenomenon of hyperconductivity, or the technical effect of hyperconductivity. Synchronously with hyperconductivity, a state of superthermoconductivity appears in the material. The phenomenon of the material turning into the superthermoconductive state represents the phenomena of superthermoconductivity, or technical effect of superthermoconductivity. Phenomenas or effects of hyperconductivity and superthermoconductivity manifest themselves at the temperature of hyperconductivity transition Tₕ synchronously, they cannot be split from each other and they exist together at temperatures above Tₕ.

The invention is based on usage of self (Inherent, I-) elastic vibrations of atom nucleuses in atoms of materials, and waves of such vibrations in materials and structures, which sources are the electron-vibration centers (EVCs). In the other words, the invention realizes hyperconductivity and superthermoconductivity based on the phenomena of effective interaction of I-vibrations of atom nucleus in atoms of materials and waves of such vibrations with electrons, holes and material's phonons. In this relation, it may be said that this invention relates to the new developing field of non-adiabatic solid state electronics.

Non-adiabatic electronics, unlike the existing, traditional and nowadays dominating adiabatic electronics, which ignores the energy exchange between atomic nucleuses and electrons, effectively uses this energy exchange in scientific and technical applications.

State of the arts. Transition of materials into the state having zero electric resistance at low temperatures is known as the superconductivity phenomenon. The superconductivity phenomenon has been discovered in 1911 [1]. Superconductivity may be seen only in some materials and only at the known conditions, namely when the material's temperature is below the temperature of superconducting transition T_{c}, and density of electric current and strength of magnetic field are both below the respective critical values Jₖ and Hₖ [2-4]. Existence of critical values T_{c}, Jₖ and Hₖ limits technical applications of superconductivity. Values Jₖ and Hₖ depend on temperature and tend to zero as the temperature rises and approaches T_{c}. First superconductors have been possessing low values of T_{c}: 4.1K (mercury—Hg), 7.3K (lead—Pb). In 1967 superconductivity in alloys of Niobium, Aluminum and Germanium compounds has been found having T_{c}≅20K. In 1986 Bednorz and Mueller had found a class of metal oxides having T_{c}≅40K. Later, many classes of high temperature superconductors have been found, and the temperature of superconductivity transition has been brought up to 133K-134K. Values T_{c} for some layered superconductors having tetragonal or orthorhombic elementary cells have the following values: (La₁₋ₓSrₓ)₂CuO₄-37.5K; Bi₂Sr₂CaCu₂O₈-80K; Bi₄Sr₄CaCu₃O₁₄-84K; YBa₂Cu₃O₇-90K; Ti₂Ba₂CuO₆-90K; HgBa₂CuO₄-94K, TlBa₂CaCu₂O₇-103K; Bi₂Sr₂Ca₂Cu₃O₁₀-110K; Tl₂Ba₂CaCu₂O₈-112K; HgBa₂CaCu₂O-121K; Tl₂Ba₂Ca₂Cu₃O₁₀-125K; HgBa₂Ca₃Cu₄O₁₀-127K; HgBa₂Ca₂Cu₃O₈-133K. Values of T_{c} for some materials having orthocubic elementary cell, including some materials based on fullerenes (A₃C₆₀), have the following values of T_{c}: K₃C₆₀-19K; Rb₃C₆₀-29K; Ba₁₋ₓKₓBiO₃-30K; RbCs₂C₆₀-33K. As it can be seen from these data, the highest values of T_{c} belong to the layered perovskite-like metal-oxides.

In the resent times the superconductivity at temperatures of about 200K has been observed in the compound SrRuO₃ subjected to a laser treatment [5], as well as in the material (Sn₅In)Ba₄Ca₂Cu₁₀O_{Y}, produced in [6] using method of reaction in the solid body having the following composition

| | | |
|---|---|---|
| SnO | 99.9% (Alfa Aesar) | 4.64 moles |
| In₂O₃ | 99.9% (Alfa Aesar) | 0.96 moles |
| CaCO₃ | 99.95% (Alfa Aesar) | 1.38 moles |
| BaCuOₓ | 99.9% (Alfa Aesar) | 5.98 moles |
| CuO | 99.995% (Alfa Aesar) | 3.29 moles |

Mixture having stoichiometric composition of these components have been granulated and baked during 36 to 60 hours at 830° C., and after that it has been burned off during 10 hours at 500° C. in the flow of oxygen.

It shall be mentioned that superconductivity in all classes of superconductive materials has been found experimentally, without theoretical prognosis, practically “blindly”. Such search for superconductive materials continues.

As the prototype for the invention, it is reasonable to choose the method of realizing of superconductivity providing the highest value of T_{c}=156K . . . 164K, which is reachable in the compound HgBa₂Ca₂Cu₃O₈ under the pressure of dozens of GaP [4], as well as the method [5] in which the material having a particular stoichiometric composition is subjected to the thermal treatment and burning-off in the oxygen atmosphere and demonstrating superconductivity at temperatures of up to T_{c}=212K, supposedly up to T_{c}=250K.

As present time, the actual task is to create and develop methods of realization of superconductivity at near-room temperatures and above, which would permit superconductive devices to operate without cooling down or heating up. This important task now is being solving by means of trying combinations of chemical compositions and material treatment technologies, i.e. still in “blind searching” of new superconductive materials having high values of T_{c}. And it is considered definite and unquestionable that at temperature below T_{c} the material will be superconductive. Expecting superconductivity exactly at T<T_{c} is traditionally based on available empiric data. Known physical models of the superconductivity phenomenon are as well based on existence of superconductive state at a temperature below T_{c}.

As well, an important task is forming electric contacts (electrodes) to the hyperconductor which would not corrupt superconductivity and would let certain electric current to pass through the superconductor and to measure electric potential of the superconductor in devices and systems.

A full valid theory of superconductors has not yet been developed, but a number of physical mechanisms have been proposed in order to explain this phenomenon. The dominating position among these mechanisms is occupied by the phonon mechanism, describing pair-wise attraction of the conductivity electrons to each other due to energy exchange between these electrons by means of virtual phonons, followed by appearing of the “electron pairs”. Energy binding electrons in these “electron pair” define the value of T_{c}. This mechanism rests in the foundation of the well known theory of superconductors by Bardin, Cooper, and Schriffer (BCS theory) [7], which nevertheless does not explain high values of T_{c} observed in experiments. The problem of high temperature superconductivity is not yet resolved, and even more, the mere possibility to achieve superconductivity at near-room and even higher temperature itself has not yet been proven. As well, absence of principal possibility to achieve superconductivity at so high temperatures has not yet been proven. It is presumed that thermal motion of particles in the material, which strengthens as the temperature (T) grows, breaks down the mutual attraction of electrons in the “electron pairs” and, at temperatures above T_{c}, the superconductive state disappears. In this relation, it is understood that superconductivity is only possible at cooling the material down to the temperatures below T_{c}, and at the temperatures above T_{c} superconductivity is impossible.

This way, the major features of the known methods of realization of superconductivity, features of analogs of the invention and of the prototype are: using a condensed material having specific chemical composition, which is chosen empirically; in some cases (like in case of the prototype) it is subjected to all-sides compression [4], or burning-off, and thermal treatments in the oxygen atmosphere [5], cooling the material down to the temperature below superconductivity transition (T_{c}), and after it the material turns to be superconductive. Its electric resistance turns into zero.

Criticism of analogs and of the invention's prototype. Known methods do not provide possibility to realize zero electric resistance i.e. hyperconductivity, and zero thermal resistance, i.e. superthermoconductivity, of a material at near-room and higher temperatures.

Matter of the invention. Purpose of this invention is to provide a method for realization of zero electric resistance, i.e. hyperconductivity, and zero thermal resistance, i.e. superthermoconductivity, caused by electron-vibration centers (EVCs) in the material between electrodes at near-room and higher temperatures.

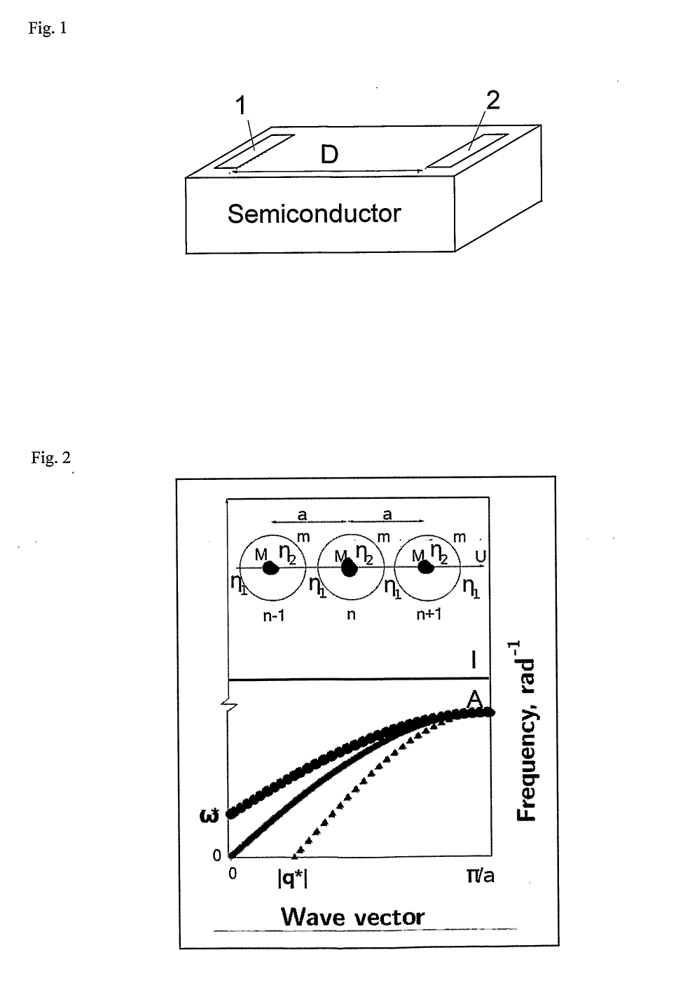

The proposed method provides realization of hyperconductive and superthermoconductive state of the material between the electrodes at the temperatures above the temperature of hyperconductivity transition Tₕ, which has a principal scientific importance and may be important for operation of certain devices and systems. The material (semiconductor) having electrodes 1 and 2 on its surface or in its volume, is shown on FIG. 1.

The stated objective is achieved by using, in accordance to claim 1, of any non-degenerate or poorly degenerate semiconductor as the material; on its surface or in its volume electrodes are located forming rectifying joints to the material, for example, joints metal-semiconductor, Schottky joints; distance between the said electrodes (D) is chosen much smaller comparing to the length of penetrating of the electric field caused by the contact difference of potentials (L) (D<<L) into the material and not exceeding the doubled coherency length (2Λ), (D≦2Λ); minimum distance between the electrodes is D_{MIN}=10 nanometers, maximum distance between the electrodes is D_{MAX}=30 micrometers; prior to, after or during forming of the electrodes, the electron-vibration centers (EVCs) are inputted into the material having concentration (N) of Nₘᵢₙ=2·10¹² cm⁻³ to Nₘₐₓ=6·10¹⁷ cm⁻³; the material is heated up to a temperature exceeding the temperature of hyperconductivity transition (Tₕ), and as the result hyperconductivity and superthermoconductivity arises in the material between the electrodes. External voltages may be applied or may be not applied to any of the said electrodes.

According to claim 2, in order to simplify the method, electron-vibration centers are inputted only into the depleted zone of the material between the electrodes, or into the parts of the depleted zone adjacent to the electrodes, and length of the current's line between the electrodes in the depleted zone is not exceeding the doubled length of coherency (2Λ).

According to claim 3, in order to simplify the method, the smallest size of the semiconductor is chosen to be not smaller than the doubled coherency length (2Λ), for example, thickness of wafer of the material is chosen to be not less than 2Λ, or thickness of layer of the material not less than 2Λ on the semiconductor, semi-insulating or insulating substrate.

According to claim 4, in order to reach hyperconductivity and superthermoconductivity in the material having dimensions strongly exceeding the doubled coherency length (2Λ), a system of electrodes is located in the volume or on the surface of the said material, for example, in form of balls, strips or spirals.

According to claim 5, in order to provide isotropic hyperconductivity and superthermoconductivity, a system of electrodes is located in the volume or on the surface of the said material, for example, in the form of droplets, and the biggest size of each of these electrodes is chosen to be much smaller comparing to the coherency length Λ.

According to claim 6, in order to control the temperature of hyperconductivity transition Tₕ and of the coherency length Λ, along a certain direction, for example along the direction of current between the electrodes in the material between the electrodes, a constant, variable or pulse magnetic field is created in the direction along, normally or at a sharp angle to this direction and having inductance not exceeding

$$B = S \frac{4 m {ω}^{2}}{e} ,$$

where m—effective mass of electron (hole), e—electron charge, ω—cyclic frequency of elastic vibration forming hyperconductive state and S—constant of the bound between this elastic vibration and electrons or holes.

According to claim 7, in order to control the coherency length Λ and the temperature of hyperconductivity transition Tₕ, the material between the electrodes is illuminated in the spectral band of self, principal, fundamental absorption of the material or (and) in the spectral band of absorption by EVCs, having intensity of up to

$$I = \frac{{N}_{C}}{ϛτ} ,$$

where N_{C}—effective number of electron states in the permitted energy zone, ζ—coefficient of optical absorption and τ—lifetime of electrons (holes).

According to claim 8, in order to control the coherency length Λ and the temperature of hyperconductivity transition Tₕ, a temperature difference is created between the electrodes having value of not more than ΔT=Sω/k, where S—constant of bound between electrons and phonons, —Planck constant, k—Boltzmann constant, ω—cyclic frequency of the phonon defining the elastic bound between EVCs in the material between the electrodes.

According to claim 9, in order to control the coherency length Λ and the temperature of hyperconductivity transition Tₕ, an additional electrode is used forming the rectifying contact or metal-insulator-semiconductor contact (MIS) to the material between the electrodes, or a number of such electrodes are used; constant, variable or pulse external voltages having direct or opposite polarities relatively to the material are applied to these electrodes (this electrode).

According to claim 10, in order to control the coherency length Λ and the temperature of hyperconductivity transition Tₕ, an alternate or constant difference of electric potentials is created between the electrodes having the value of up to Sω/e , where S—constant of electron-phonon bound, —Planck constant, ω—cyclic frequency of elastic vibrations of the material, for example, frequency of phonon or I—oscillation of nucleus in atoms of the material, e—electron charge.

According to claim 11 in order to control the coherency length Λ and the temperature of hyperconductivity transition Tₕ, a flow of sound, ultrasound or hyper-sound is directed into the material between the electrodes having frequency f and volume density of its energy up to (2πSfN)/τ, where S—constant of electron-phonon bound, N—concentration of EVCs, τ—lifetime of electrons (holes) in the material between the electrodes, —Planck constant.

According to claim 12, in order to stabilize hyperconductivity and superthermoconductivity, thickness of the semiconductor wafer, or thickness of the semiconductor layer on a substrate, or thickness of the substrate, or total thickness of the semiconductor layer on the substrate and the substrate, or distance (distances) between mutually parallel edges of the semiconductor are chosen equal or divisible by W=ν/2f, where ν—phonon (sound) speed having frequency f, propagating between the said mutually parallel edges of the semiconductor, the substrate, or the semiconductor and the substrate, f—frequency of the phonon defining the elastic bound between EVCs in the material between the electrodes.

According to claim 13, in order to stabilize hyperconductivity and superthermoconductivity, thickness of the semiconductor wafer, or thickness of the semiconductor layer on a substrate, or thickness of the substrate, or total thickness of the semiconductor layer on the substrate and the substrate, or distance (distances) between mutually parallel edges of the semiconductor are chosen equal or divisible by W=ν/2f, where ν—speed of the sound propagating between the mutually parallel edges of the semiconductor, the substrate and the semiconductor and the substrate, f=1/P, where P—period of alternate electric or magnetic field created in the material between the electrodes.

Comparative analysis of the invention and the prototype shows that the claimed method is distinguished by using non-degenerate of poorly degenerate semiconductor material; by using electrodes forming rectifying joints to the material, separated by a gap having certain width, and located on the surface or in the volume of the material; by imputing electron-vibration centers into the material or into certain parts of the material, having certain concentration; by creation of the magnetic field having certain strength and direction in the material; by creating the temperature difference having certain value between the electrodes; by illuminating the material in the specific spectral band and at the specific intensity; by creation of the difference of potentials between the electrodes; by using additional electrodes forming joints to the material; by applying voltage between the additional electrodes and the material; by heating the material up to the temperatures exceeding the temperature of hyperconductivity transition Tₕ. Realization of this complex of features of the present invention causes arising of hyperconductivity and superthermoconductivity in the material between the electrodes, which corresponds to the purpose of the invention.

This way, the proposed method of realization of hyperconductivity and superthermoconductivity satisfies the criteria of “novelty” for inventions.

Comparing the proposed method of realization of hyperconductivity and superthermoconductivity to the prototypes and other technical solutions in this field of technology did not reveal any technical solutions possessing similar features. This lets to make a reasonable conclusion that the claimed technical solution meets the criteria of “amount of invention”.

As the matter of fact:

From a physical point of view, in the claimed invention, a mechanism of superconductivity is realized, which is based on attraction of two or more electrons or holes to the electron-vibration center by means of self, I-oscillations of the electron-vibration center interacting with material's phonons, electrons (and/or holes). The mechanism of hyperconductivity, realized in the invention is by some features identical to the mechanism based on pair-wise attraction of electrons to each other by means of virtual phonons, considered in the BCS theory [7] with the difference that in the present invention function of virtual phonons is realized by I-oscillations of atom nucleus existing inside electron shells of atoms, bound to phonons and having higher Debye temperatures. Due to higher energies of elementary quanta of self, I-oscillations (not less than 0.22 eV) hyperconductivity and superthermoconductivity of materials at very high temperatures are possible. In order to actuate self oscillations, high temperatures are needed, and at the temperatures above Tₕ conditions for existence of self oscillations, hyperconductivity and superthermoconductivity in certain zones of the material—in the zones of coherency, become advantageous and these oscillations may presumably exist up to the temperature of the material's melting, and even in the melted material.

After discovery of superconductivity phenomenon in 1911, numerous efforts have been applied in order to create a theory of superconductivity. Various physical mechanisms have been proposed for this phenomenon, various superconductive materials and methods for their production have been developed and researched. By now, the temperature of superconductivity transition has been increased from units up to more than two hundred degrees Kelvin and approaches the room temperature. And despite that, superconductors working at the room and higher temperatures do not yet exist [2-4]. At the same time, an acute need for materials having zero electric and thermal resistance, in hyperconductors and superthermoconductors able to work at near-room and higher temperatures is present.

Functioning of majority of superconductors is based on interaction between electrons and virtual phonons. But thermal motion of particles in materials grows as the temperature (T) grows, and it breaks down the bound between electrons in the electron couples and this is why at temperatures above T_{c} superconductive state disappears. Within this approach to the superconductivity, its realization at high temperatures looks possible in case if phonons of the material are unable to break down the mutual bound of electrons provided by virtual phonons, and this is the principle realizable in case if the quanta of the virtual phonon exceeds the quanta of elastic vibrations of the material (quantum of the material's oscillations) and bound of electrons by means of such virtual phonons is sufficiently effective.

It is helpful to estimate the value of T_{c} by using the respective analytical expressions, received in the theory of superconductors and by setting that the function of virtual phonons in our case is realized by the phonons having energy E_{pf}=ωₚₕ=kT₀. This way, in the theory of Eliashberg, accounting the delay of exchange with virtual phonons, in approximation of small electron-phonon bound (S˜1), related to BCS theory, the temperature T_{c}=T₀exp(−S⁻¹). Accepting the typical acoustic phonon E_{pf}≅21 meV as the virtual phonon for silicon, we are getting T_{c}≈206K. In case if optical phonons are the virtual ones, then E_{pf}≈55 meV and T_{c}≈539K. In the approximation of strong bond (S>>1) Allen and Dainess have showed that

$${T}_{c} = \frac{0 , 15}{k} {( S < ℏ {ω}_{pf}^{2} > )}^{1 / 2} ,$$

where < > means the operation of averaging. Accordingly, T_{c}≈144K for virtual acoustic phonons and T_{c}≈495K for optical phonons in silicon. These estimations of T_{c} forecast possibility for superconductivity to exist at the room and higher temperatures, which has not yet been achieved.

T_{c} may be increased by using virtual phonons having higher energies and providing sufficiently strong bound of these phonons to electrons (holes), i.e. by providing higher value of the constant of electron-phonon bound S. Such possibility to increase T_{c} has been proposed in works [8, 9], and it is as well contained in BCS [7]. In this relation, propositions have been made to use other, energetic phonons as the virtual ones, for example elastic vibrations of the crystalline lattice having the wave vector exceeding the size of Brillouin zone. But such mechanisms of superconductivity have never been realized experimentally.

At present, it is the established fact of existence of self, I-oscillations and waves in crystals having high energies of elementary quanta (not less than 0.22 eV) and high Debye temperatures (above 2500K) [10-15]. In this relation, the possibility gets opened to realize hyperconductivity and superthermoconductivity at near-room and higher temperatures.

Theories explain superconductivity by effective interaction between electrons and elastic vibrations of materials which correlates to the results of optical, microwave, ultrasonic and other researches, and as well it is confirmed by the isotopic phenomenon. This way, BCS theory [7] lets to determine major parameters of superconductors and to calculate characteristic temperatures of the superconductivity transition

$${T}_{c} = 1 , 13 {T}_{D} exp ( - \frac{1}{V * N ( F )} ) , \qquad ( 1 )$$

where T_{D}=ω_{D}/k—Debye temperature of the elastic vibration of the material bound to electrons (holes), ω_{D}—quantum and ω_{D}—Debye frequency of this vibration, —Planck constant, k—Boltzmann constant, V*—energy of bound between the elastic vibration of the material and electron, N(F)—density of electron states at Fermi energy, F—Fermi energy. For example, in the superconductive materials V*N(F)<<1, T_{D}≦200K, and this is why T_{c} is not exceeding 20K. On the contrary, T_{D} in the semiconductors containing EVCs and calculated values of T_{c} are high; they may even exceed melting temperatures (Tₘₑₗₜ) of the materials.

It is deemed that formula (1) is correct only for low temperature superconductivity. This opinion cannot be considered as final, because quite energetic elastic vibrations are possible in materials, and strengthening of their bound to electrons is able to increase T_{c} many times. It can be seen out of formula (1) that in order to reach higher values of T_{c}, it is important for the elastic vibrations of the material having high Debye temperatures T_{D} (having higher Debye frequencies ω_{D}) to be strongly bound to electrons, i.e. so the energy V* and density of the states N(F) would be sufficiently high. These electrons bound to the elastic vibrations of the material provide superconductivity of the material.

This is why it is reasonable to analyze possible types and quanta of elastic vibrations of condensed materials. We will do this by using the case of single-dimensional material, though the reached conclusions can naturally be generalized on three-dimensional crystals as well as on liquid state, polycrystals, amorphous materials and other states of materials, if we will consider interaction between atoms in them.

Traditionally it is accepted to analyze vibrations in the materials by analyzing motion equations of the crystal models. In such models atoms are substituted by particles having masses equal to the mass of the atom. These models do not correspond to adiabatic model of the crystal. Actually, the adiabatic theory lets to describe separate and independent motion of electrons and nucleus in the crystal. But in the traditional crystals, atom is substituted by a single particle, consequently, nucleus and electrons of each atom are considered rigidly bound to each other. Because in such conditions energy exchange between nucleus and electron is possible, adiabatic principle in such models of materials is not followed. Problem of superconductivity is partially not resolved due to such imperfect models of crystals and, respectively limited descriptions of crystal oscillations. New physical properties of crystals may be discovered by researching the adiabatic models of crystals. In this relation, it has been important to develop adiabatic model of a crystal and to research it.

Description of the adiabatic model of a crystal. Adiabatic model of a crystal may be developed in accordance with the adiabatic approximation traditionally used in solving the static Schrödinger equation for the material: (Tₑ+T_{Z}+V)Ψ=WΨ, where Tₑ and T_{z}—operators of kinetic energy of electrons and nucleus, V—crystalline potential, Ψ—wave function and W—energy of the material. Putting Ψ=Φφ and splitting variables, it is possible to bring the original Schrödinger equation to the following two equations:

(Tₑ+V)φ=Eφ, (2)

(T_{z}+E+A)Φ=WΦ, (3)

where E—energy of electrons and A—adiabatic potential. Wave function φ describes motion of electron in crystalline potential field V. Wave function Φ describes motions of atom nucleus. Due to presence of adiabatic potential A in the equation (3), functions φ and Φ, as it is known, are mutually dependent, and electrons and nucleus are able to exchange energy between each other. This is why the problem of researching of crystal vibrations basing on the equations (2) and (3) in general case is non-adiabatic. But, in the case if potential A is small and its share into the crystal's energy may be neglected, then the adiabatic approximation by Born-Oppenheimer [16] is used. In this approximation, energy exchange between nucleus and electrons in crystals is absent and the equation (3) may be resolved independently of the equation (2). Further, method of Hartry-Fok may be applied to the equation (3) [17, 18] in order to determine the effective potential V(Rⱼ) which depends on coordinates of only j-th nucleus, and to bring the problem of nucleus motions down to the single-particle task: [Tⱼ+V(Rⱼ)]Φⱼ=WⱼΦⱼ, where Φⱼ wave function of nucleus, Tⱼ—operator of kinetic energy of nucleus, Wⱼ—energy spectrum of stationary vibrations of j-th nucleus in the effective potential field V(Rⱼ). Potential V(Rⱼ) is defined by all electrons and nucleus of the crystal except j-th nucleus. Analysis shows that the major share into V(Rⱼ) is brought by s-electrons of K, L and M electron orbitals of j-th atom. Minimum of V(Rⱼ) defines the position relatively to which nucleus can do oscillatory motions. In [19] it is shown that adiabatic approximation is reasonable to the sufficient extent if the energy of nucleus oscillations is lower than the energy of electron transitions. Yet another condition of reasonability of the adiabatic approximation by Born-Oppenheimer is known [20]. Under such conditions vibration energy of nucleus cannot be transferred over to electrons. This is why electron shells of atoms stay unchanged, motionless during process of vibration motions of atom nucleus. Such vibrations of nucleuses relatively to the electron shells may be called self (I-) oscillations, because their properties depend on internal (Inherent) parameters of the atom: mass and charge of the nucleus, potential V(Rⱼ) near the center of the electron shell. Consequently, in the adiabatic model of a crystal, each atom represents self, I-oscillator describing displacements of its nucleus relatively to its electron shell, to which it is bound by quasi-elastic force [10, 11, 13, 14].

Vibrations of nucleuses relatively to the electron shells exist in small limits (≈10⁻² A⁰) and, generally speaking, they shall be researched using quantum methods. But in case of interest in harmonic oscillations, it is convenient to use known correspondence between the results of quantum and classical theories of harmonic oscillator. This correspondence consists in matching of frequency of transitions between adjacent quantum levels of the harmonic oscillator to the classic frequency of its oscillations. This is why energy spectrum of harmonic oscillations may be researched by classic methods. We have used this possibility for describing harmonic oscillations and waves of the adiabatic model of the simple chain of atoms. The model is shown at the top of FIG. 2. Electron shells of atoms are shown as circles, in their center s nucleuses are shown by dots, the constant of the chain is a. Displacements of the shells and nucleuses of atoms away from the positions of their equilibrium are marked U′ and U″. Coefficients of quasi-elastic forces rising at relative displacements of shells of the adjacent atoms are marked as η₁, and at relative displacements on nucleus and the shell—as η₂. System of the classic motion equations of this model may be written down the following way:

Md²/dt²U′ₙ=−θ₁(U′ₙ−U″ₙ) (4)

md²/dt²U″ₙ=−θ₁(U″ₙ−U′ₙ)−θ₂(2U″ₙ−U″ₙ₋₁−U″ₙ₊₁) (5)

where M—mass of the nucleus, m—mass of the electron shell, t—time, n=0, ±1, ±2, ±3 . . . —number of elementary cell. If we will look for solution of the system of equations (3) and (4) in the form of harmonic waves, then the dependence of cyclic frequency ω from the wave vector q may be put down this way:

ω_{1.2}(q)=(Y/2){1±[1−(4θ₁θ₂/Mm Y²)]^{1/2}}, (6)

where Y=β/m*+γC/m, C=4 sin² (aq/2), m*=(1/M+1/m)⁻¹. Curves ω_{1,2}(q) are qualitatively shown at the bottom of FIG. 2. This is the known acoustic branch (A) and the branch of self, I-oscillations (I). In the complex three-dimensional crystal, besides acoustic and optic branches, I-oscillations are present as well. Number of self, I-branches is trice larger than the number of atoms in elementary cell of a crystal, because two branches of transverse and one branch of longitudinal I-oscillations exist. I-oscillations and waves may exist in crystals even if there is only one atom in its elementary cell and there are no optical vibrations.

Characteristic properties of self, I-oscillations and waves. Energy spectrum of self oscillations and waves may be defined by accounting the interaction between self oscillations of different atoms. Displacements of electron shells due to interference between them are coherent in the limits of certain zones of coherency having characteristic dimension A. Motions of electrons in the coherency zone are described by coherent wave functions, i.e. by functions having similar phases. Due to this, electrons within the coherency zone are moving without fluctuation of energy, providing zero electric resistance, i.e. hyperconductivity, and zero thermal resistance, i.e. superthermoconductivity in this zone. In the other words, coherency zones are hyperconductive and superthermoconductive zones of the material. Thermodynamic analysis of the adiabatic model of the crystal provides the following expression for the length of coherency Λ=[Zₐᵥᵣ m*/ne²μ]^{1/2}, where Zₐᵥᵣ—average atomic number of the atoms forming the crystal, m*—effective electron mass of the electron shell, e—electron charge, n—electron density, μ—magnetic constant. Value of m* may reach the mass of the coherency zone, this is why coherency length Λ may exceed dozens of crystal constants and reach dozens of microns. In such conditions the nucleus of each atom may realize oscillations relatively to a large mass of the coherency zone in the material.

Determining quanta of I-oscillations of nucleuses inside the electron shells of atoms. It can be seen out of the equation (3) that in the adiabatic approximation (when adiabatic potential A≡0) the potential field acting on the nucleus matches full energy of electrons, which in neutral atom contains the following summands:

E=T_{c}+E_{ze}+Eₑₑ+Eₑₓ, (7)

where Tₑ—kinetic energy of electrons, T_{ze}—energy of electrons' attraction to the nucleuses,

$${E}_{ee} = \frac{1}{2} \int Φ ( r ) χ ( r ) d Ω - energy of their repulsion ,$$

Eₑₓ—exchange energy, dΩ—three-dimensional element of space. Electron density χ(r)=eΣᵢ₌₁^{z}|φ(r)|², Φ(r)—electrostatic potential, produced by the electron shell in the point r, e—electron charge, Z—atomic number, i—number of the electron. Cyclic frequency of harmonic oscillations of the nucleus in the potential field (7) equals to ω=(β/M)^{1/2}, where β—coefficient of the elastic force binding the nucleus and the shell. This frequency ω, as it is known, equals to the difference of the adjacent frequencies of oscillations of the quantum harmonic oscillator. Considering this, we will move to calculation of frequencies of nucleus self-oscillations in various atoms.

In the atom of hydrogen (Z=1) Eₑₑ=0, E_{each}=0 and according to the virial theorem Tₑ=−E_{Ze}/2. Normalized wave function in the principal state of hydrogen atom Ψ=(π/a)^{1/2}exp(−r/a), where a—Bohr radius. Integrating twice the Poisson equation

$$\frac{1}{r} \frac{{d}^{2}}{d {r}^{2}} ( r Φ ) = 4 π e {\vert Ψ \vert}^{2}$$

having border conditions Φ(r=∞)=0, Φ(r=0)=const we get Φ(r/a)=e²{(r/a+1)exp(−2r/a)−1}/a. Expanding Ψ(r/a) into a power series and dropping members containing (r/a) in powers higher than the second power, we determine the parabolic potential E″(r), in which oscillations of the nucleus are harmonic, and calculate the coefficient of elastic force β₁=(d²E″(r)/dr²)ᵣ₌₀=(e²/a³)/(6π∈₀), where ∈₀—electric constant. Further calculate the elementary quantum of oscillations of hydrogen nucleus ω₁=\sqrt{β₁/mₚ}≈0.519 eV, where mₚ—proton mass.

In atom of helium (Z=2) two electrons in the principal state have the wave functions Ψ=(4π)^{-1/2}(Z*/a)³exp[(−Z*r/a)], where Z*=2−5/16≈1.6875—effective charge of the nucleus, different from 2 due to shielding of the nucleus by electrons [18, c. 338]. We will simplify formula (7) using virial theorem and the property of two-electron system, for which E_{each}=−Eₑₐ/2. We arrive to the result: E(r)=2ZeΦ(r)/4. Similarly to calculations for hydrogen atom, we are integrating Poisson equation having electron density e|Ψ(r)|², determining Φ(r) and β₂=(Ze²)(24π∈₀)⁻¹(Z*/a)³. Then determining the energy of quantum of self oscillations of nucleus of helium atom ω₂=\sqrt{(Ze²)(24π∈ₒ)⁻¹(Z*/a)³{2(mₙ+mₚ)}⁻¹}≈0.402 eV, where mₚ and mₙ—masses of proton and neutron respectively.

In multi-electron atoms the potential field is spherically symmetric and normalized radial wave function of arbitrary electron state may be expressed by means of hyper-geometric function F(a,b,c,) [19, c. 176]:

$${R}_{nl} = {{N}_{nl} ( \frac{2 Zx}{n} )}^{l} F ( - n + l + 1 , 2 l + 2 , \frac{2 Zx}{n} ) exp ( \frac{- Zx}{n} ) , \qquad ( 8 )$$

where Nₙₗ=[(2l+1)!]⁻¹\sqrt{(n+1)/{2n(n−l−1)!}}(2Z/n)^{3/2}, x=r/a, n—principal and l—orbital quantum numbers. It is followed out of the equation (8) that near the center of the shell the electron density is created mainly by s—electrons, and shares of p, d, e, f, . . . —electrons are insignificant. Density of K—electrons (n=1) is complemented by s—electrons of L, M, N, . . . orbital (n=2, 3, 4, . . . ). Part of density of these states may be determined as squares of relations of the respective radial wave functions: (R₂₀/R₁₀)²≅0.125; (R₃₀/R₁₀)²≅0.037; (R₄₀/R₁₀)²≅0.0123. This way, it can be seen that share into the electron density of 2 s, 3 s, 4 s electrons constitutes approximately 17.4% which may cause increasing of frequencies of nucleus oscillations not more than 5% up [21]. In multi-electron atoms shielding of the nucleus charge by electrons is accounted using the effective nucleus charge Z*=Z−s, where s=σ·Z^{1/3}, values of σ differ from 1 insignificantly [22, t. 2, p. 153]. Calculating, accounting these data, the energies of quanta of nucleus self-oscillations (quanta of α-type of nucleus I-oscillation) in atoms having numbers 2≦Z≦80 lies between 0.22 eV and 0.402 eV. Minimal value relates to the atom of oxygen (ω₈≅0.22 eV). The same result appears in case of applying to s—electrons the theorem speaking about potentials of ellipsoid, according to which inside the evenly charged ellipsoid the potential is uniform.

Analysis shows that α, β, γ-types of self elastic vibrations and waves exist depending on displacements of K and L orbital. Inherent oscillations of α-type represent vibrations of nucleus relatively to the electron shell. Inherent oscillations of β-type represent joint vibrations of nucleus and K orbital relatively to the rest of the shell. Inherent oscillations of γ-type represent joint vibrations of nucleus, K and L orbital relatively—of the rest of the shell. Elementary quantum of self oscillations of α—type for neutral atom having number Z>8, calculated accounting shielding of the nucleus by electrons may be written the following way:

$$ℏ {ω}_{z} = \sqrt{\frac{{e}^{2}}{3 π {ɛ}_{0} ( {m}_{n} + {m}_{p} )} {\{ ( \frac{ϑ}{{a}_{0}} ) \frac{Z - ζ - ξ}{Z - ζ} \}}^{3} \frac{χ ( Z - ξ )}{Z}} . \qquad ( 9 )$$

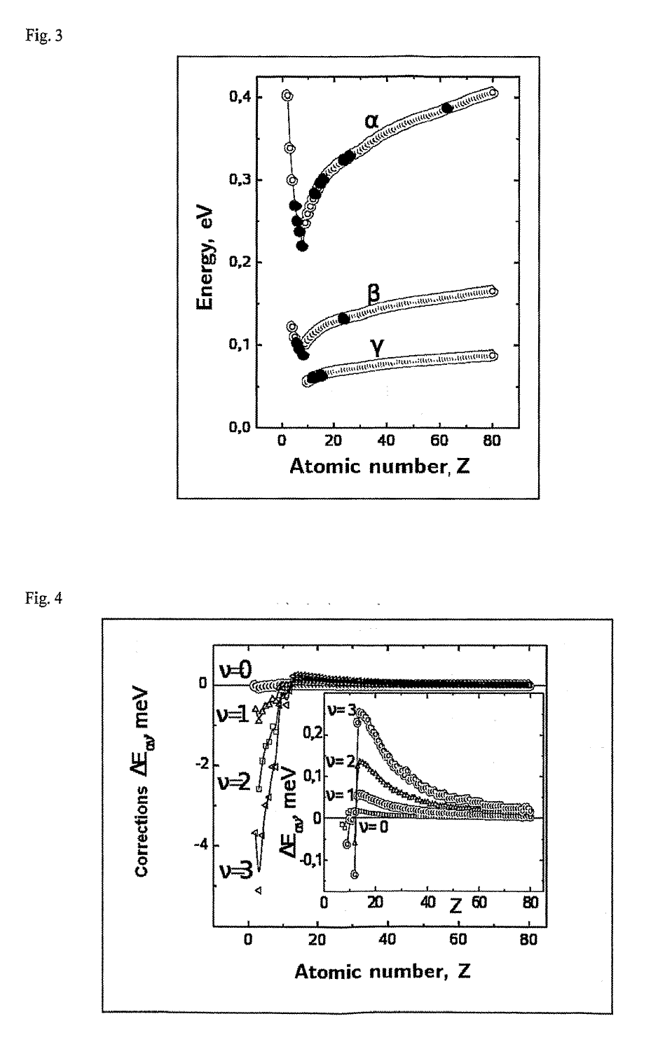

Shielding is accounted by the values ζ=5/16 and ζ=η^{1/3}, η varies from 1 to 1.15 at Z changing from 8 to 80, χ=1.2 accounts the share from s states of L, M, N orbital in the electron density, ∂=0.88534, ∈₀—electric constant, mₙ and mₚ—masses of neutrons and protons, a₀—diameter of the first Bohr orbit in the atom of hydrogen. Elementary quant of self oscillations of β-type may be similarly determined using formula (9) putting χ=0.2. Elementary quantum of self oscillations of γ-type may be determined using formula (9), putting χ=0.056. Calculated values of quanta of I-oscillations (ω_{z}) and the experimental values of quanta of I-oscillations for some atoms are presented on FIG. 3 depending on atom number Z.

Anharmonicity of I-oscillations of atom nucleuses. Spherically symmetric potential field near the center of the electron shell, where the atom nucleus is moving, may be written in the form of power series

E(x)=(Z*e²/a){−2+x²/3−x³/3+x⁴/20−x⁵/90+ . . . }, x=2r/aZ*.

This function differs from the parabolic connection, and due to this unharmonious corrections appear to the energy of harmonious oscillations. Corrections for single-directional oscillations of α-type (ΔE_{αv}) having oscillation numbers v=0, 1, 2 and 3 have been calculated [21] in the first and second orders of the perturbation theory according to [22, p. 93]. As it should be expected, maximum values of these corrections relate to oscillation states having v=3, having the biggest displacements of nucleuses. FIG. 4 graphically shows corrections to the energy of α-type I-oscillations in the states having v=0, 1, 2, 3 for atoms depending on atom number Z. In the insert of the FIG. 4 corrections are presented in the different scale for atoms having Z>10.

Experiments show that I-oscillations of α-, β-, γ-types are the single-dimensional oscillations. This is why formula of linear harmonic oscillator may be used for calculation of such oscillations:

E(v)=ω_{z}(½+v), (10)

where oscillatory quantum number v=0, 1, 2, . . . . Energies of “zero” oscillations E(v=0)=ω_{z}/2 together with E=ω_{z} and energies of oscillations related to v=1, 2, . . . participate in optical and electric processes, which is prohibited for the free quantum oscillator. This provides a reason to consider oscillations of atom nucleuses in the material to be not completely free and exchanging energy with electrons, which as well corresponds to violation of the adiabatic approximation. This way, self oscillations of nucleuses in materials demonstrate dualism of properties, showing both quantum and classical properties, because oscillatory energies are quantified, but energy in the minimum of parabolic potential is still available, which is typical for classic oscillator, or for not free classical oscillator.

Interaction between inherent oscillations and phonons. Inherent oscillations and waves are able to exist in the ideal (defectless) material, but such vibrations and waves may be created, actuated, for example, by means of recombination energy of electrons and holes, by means of local centers having strong electron-phonon interaction. Such centers have been called the electron-vibration centers. Self oscillations and waves distort the material and they are able to interact with phonons, electrons and holes, by this providing an effective interaction of electrons with electron-vibration centers and phonons. This may be the cause for electron drag by phonons and for other physical phenomena.

Interaction of self vibrations and waves with acoustic phonons may be traced using the example of adiabatic model of a simple linear chain of atoms, by adding the additional force (−δUₙ″) into the equation (4). This force represents the share of displacements of the coherency zones. Respective dispersion curves ω(q) may be received by switching Y into (Y+δUₙ″) in the expression (6). Acoustic branch experiences the strongest changes in the center of Brillouin zone. In the case when δ is higher than 0 (δ>0) a zone of prohibited frequencies 0 . . . ω* appears. In the case when 6 is smaller than 0 (δ<0) a prohibited zone for wave vectors 0 . . . q* appears. Dispersion curves ω(q) at δ>0 and δ<0 are qualifiedly show on FIG. 2 as dotted lines.

Acoustic phonons meeting the conditions 0<ω<ω* with q=0 at δ>0 and 0<|q|<|q*| at δ<0 cannot exist in the crystal and cannot dissipate mobile charge carriers. This is why in absence of other mechanisms of charge carriers' dissipation a zero electric and zero thermal resistances are possible, i.e. hyperconductivity and superthermoconductivity are possible.

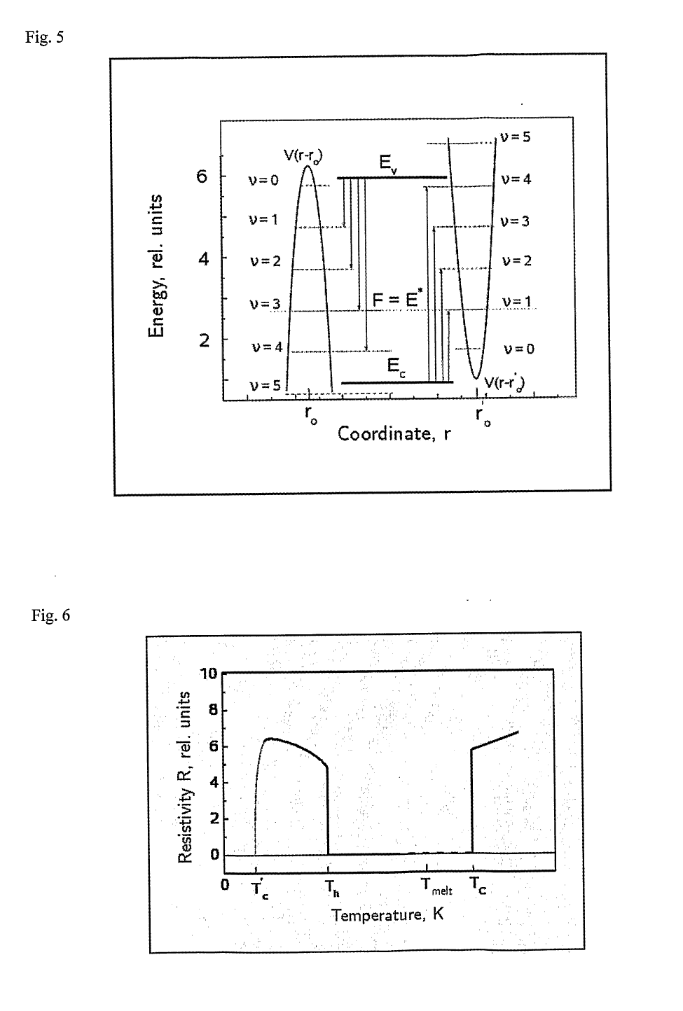

Energy diagram of the hyperconductor. Electron-vibration energy levels of EVCs described by formula (10) manifest themselves in semiconductors in the form of so-called deep energy levels, located in the prohibited band of the semiconductor. According to the data on recombination of electrons and holes at EVCs, some of electron-vibration levels of EVCs are really located in the prohibited band of the semiconductor as shown on FIG. 5. In the center of FIG. 5 the energy band of the semiconductor is shown where E_{c} and Eᵥ represent energies of the bottom of conductivity band and of the ceiling of valence band, F—Fermi level. Considered electron-vibration centers are located in the volume of the semiconductor, in the points having coordinates rₒ and rₒ′. Parabolic potentials holding atom nucleus in the center of electron shell of EVC, are shown to the left and to the right on FIG. 5 by parables V(r−r₀) and V(r−r₀′). Energy levels of EVCs having various values of oscillatory quantum number v=0, 1, 2, . . . are shown by horizontal dotted lines. Electron transitions from conductivity band onto the oscillatory levels of EVCs having v>0 are shown on FIG. 5 as vertical arrows pointing downwards from E_{c}. Transitions of holes onto the oscillatory levels of EVCs are shown by vertically pointing arrows up from Eᵥ. For this, branches of parable V(r−r₀) shall be turned up as it is shown in the left part of FIG. 5. Exactly such disposition of potential curves V(r−r₀) corresponds to excitation of I-oscillations of EVCs by means of energy of electron (or hole) transitions. These transitions are primarily happening together with irradiation or absorption of a few material's phonons, excite I-oscillations of atom nucleuses in atoms of EVCs and due to this they are the electron-vibration transitions. Electron-vibration process on EVCs may be described as serial, periodic alternation of the electron-vibration transition out of conductivity band (out of valence band) on EVC followed by emission of electron (hole) from EVC by means of energy of I-oscillation of atomic nucleus and phonons. Each atom which nucleus makes free or forced I-oscillations, may be reasonably considered as I-oscillator which oscillation energies are described by formula (10).

Thanking to the strong electron-phonon bound, EVCs possess a larger trapping cross-section for electrons (holes) because of which electrons and holes are localizing on the mentioned electron-vibration levels of EVCs. Besides, one of the levels having quantum number of v=v* is dominating in processes of recombination of the charge carriers. As the result, electric charges are accumulating on this level and exactly here Fermi level F=E(v*)=E* is getting fixed. Density of electron-vibration states on Fermi level is N(F)=N*·δ(E*−F), where N*—density of states having the energy of E*, δ(E*−F)—Dirac's delta function. It is obvious that N* exceeds the average density of states which is equal to N/ω_{Z}, where N—concentration of EVCs, and it may be seen out of FIG. 5 that V*=(E_{c}−E*)≧ω_{z}. In case if at least one electron is localized on each center (on average), than, for each single volume of the material (1 cm³) the multiplication V*N(F)≧N≧10¹². Due to this, the exponent included into the expression (1) practically turns into 1, and calculated temperature of superconductivity transition T_{c}≅1.13T_{D}. For example, for the Silicon containing A—centers, it comes to T_{c}>2900 K. The respective, expected, calculated using BCS theory, temperature dependence of electric resistance (R) of the hyperconductor, i.e. of the semiconductor containing EVCs, is qualitatively shown on FIG. 6 as the solid line. It matches zero value of resistance in the temperature band from Tₕ to T_{c}. It can be seen out of FIG. 6 that the hyperconductor's resistance turns into zero at the temperatures much higher than hyperconductive transition Tₕ, and at T<Tₕ it has a finite nonzero value. Generally speaking, traditional superconductivity may arise in the hyperconductor at low temperatures, below T′_{c}<Tₕ, as it is qualitatively shown by dotted line on FIG. 6.

Determining the temperature of hyperconductivity transition Tₕ.

The value of Tₕ may be found using parameters of the material. Actually, according to the theory of electron-vibration transitions [23-26] in such a transition on an EVC, S phonons participate on average. In the stationary state electrons (holes) are mainly localized on the energy level E* (see FIG. 5) and the material has its conductivity close to its self-conductivity. Speed of thermal generation of electrons in the material is equal to the speed of their recombination on EVCs. The following expression [11] comes out of this condition, linking together concentration of electron-vibration centers N, temperature of hyperconductivity transition T=Tₕ and constant of electron-phonon bound S:

$$\sqrt{{N}_{C} {N}_{V}} exp ( - \frac{{E}_{g}}{2 kT} ) = \frac{{N}_{m i n}}{S ( exp \frac{E ( v )}{kT} - 1 )} , where \\ {N}_{c} = 2 {( \frac{2 π {m}_{nd}^{*} kT}{{h}^{2}} )}^{3 / 2} and {N}_{V} = 2 {( \frac{2 π {m}_{pd}^{*} kT}{{h}^{2 }} )}^{3 / 2} - effective densities of states of electrons in the conductivity band and for holes in the valence band of the semiconductor , \qquad ( 11 )$$

m_{nd}* and m_{pd}*—generally accepted denotation for effective masses for densities of states of electrons and holes respectively, h=2π, E(v)—oscillation energy of EVCs.

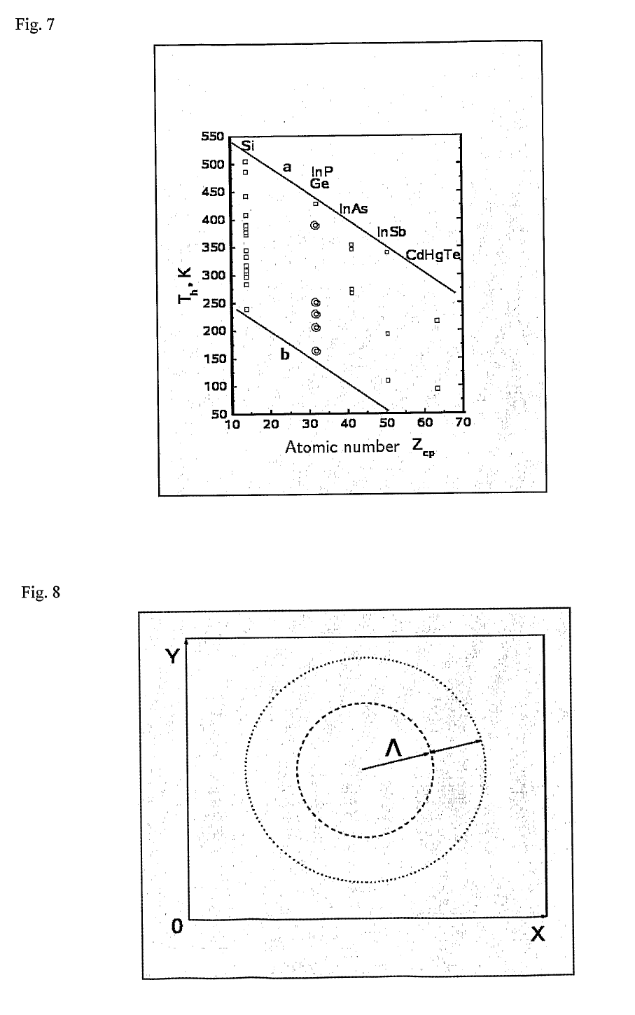

Using formula (11) values of Tₕ have been calculated for a number of k semiconductors containing minimum (Nₘᵢₙ) and maximum (Nₘₐₓ) concentrations of EVCs depending on the average value of atomic number of the material (Zₐᵥᵣ), related to the inclined straight lines a and b, FIG. 7. Experimental values of Tₕ for some materials are presented on FIG. 7 by experimental dots. It can be seen out of FIG. 7 that the experimental values of Tₕ for each semiconductor are laying between the calculated temperatures of hyperconductivity transition, which are corresponding to the minimal (angled line a) and maximal (angled line b) concentrations of EVCs. This way, the calculated and the experimental values of Tₕ match the considered recombination mechanism of excitation of the EVC's I-oscillations.

The experimental values of Tₕ on FIG. 7 are located between these two parallel lines a and b and correspond to the different concentrations of EVCs having values between Nₘₐₓ and Nₘᵢₙ. For the material having a particular value of Zₐᵥᵣ, the value Tₕ is as higher as EVCs concentration is higher. At a particular concentration of EVCs the value of Tₕ is decreasing if the average atomic number of the material Zₐᵥᵣ is increasing. Data shown on FIG. 7 permit to quite definitely predict, calculate using formula (11), define, forecast, set a particular value of Tₕ by inputting a certain concentration of EVCs into the material between the electrodes.

Comparison of the data concerning values of Tₕ presented on FIG. 7 with preliminary estimations of Tₕ shows that for silicon the most acceptable is the approximation of weak bound despite the fact that S strongly exceeds 1. The experimental values of Tₕ for various silicon samples are located between the values of Tₕ estimated in participation of acoustic and optical phonons, and it provides a reason to accept that the value Tₕ is defined by mutual share of both acoustic and optical phonons. This corresponds to the properties of A-centers, equally actively interacting with both these types of phonons.

The considered mechanism of hyperconductivity is different from the known mechanisms of superconductivity. Actually, known superconductors are characterized by the fact that superconductive state in them appears at the temperatures below the temperatures of superconductivity transitions T_{c}. On the contrary, hyperconductivity appears at the temperatures above the temperature of hyperconductivity transition Tₕ and below the temperature of superconductivity transition T_{c}. Because hyperconductivity is defined by interaction of self oscillations and waves and acoustic phonons, its appearance shall be expected at high temperatures, when material's phonons, I-oscillations and waves are excited and existing, and it may happen at a relatively high temperature. Experiments confirmed that hyperconductivity appears and exists at the temperatures above Tₕ and up to the temperatures where interaction of self oscillations and waves with phonons exists, up to the melting temperature and probably above the melting temperature of the material.

Determining the coherency length Λ. Recombinating electrons and holes are generating I-oscillations of electron-vibration centers, because of which EVCs behave like harmonic I-oscillators. Research of electron-vibration transitions at EVCs showed that I-oscillators demonstrate dualism of physical properties. On one hand they possess discrete spectrum of oscillatory energy levels described by formula of quantum harmonic oscillator (10). On the other hand, electric, thermoclectric and optical phenomenas are participated by so called <<zero oscillations>> of I-oscillators having energies of ω_{Z}/2, corresponding to v=0, which is not typical to the quantum oscillator but acceptable for the classic oscillator. In relation with this result, we will use not only quantum but as well classic description of I-oscillations.

In general case, frequencies of EVC's I-oscillations are differing from the frequencies of I-oscillations of atoms of the main material. But all atoms in the vicinity of EVC form a continuum of I-oscillators vibrating at the same frequencies, because in the atoms of the main material forced I-oscillations of atom nucleuses are happening having typical for EVCs frequency of ω*=E*/ corresponding to the quantum number v*. Actually, according to [27], classic equation for forced oscillations of an oscillator may be written down the following way:

$$\frac{{d}^{2} x}{d {t}^{2}} + 2 r \frac{d x}{d t} + {p}^{2} \cdot x = F cos ( ω * t + ϕ ) , \qquad ( 12 )$$

where x—displacement of atom nucleus of the main material, t—time, r—coefficient describing fading of oscillations, p—cyclic frequency of self oscillations of atom nucleuses in atoms of the main material, F—amplitude, φ—phase, ω*—frequency of forcing oscillations acting on an atom of the main material from EVCs. Because under the static conditions r, p and F are not depending on time, then this equation, having the constant coefficient, describes the forced oscillations of fading harmonic oscillator, and its solution is

x(t)=e^{-rt}(C₁ cos qt+C₂ sin qt)+A cos(ω*t+φ−φ) (13)

where amplitude of the forced oscillations

$$A = \frac{F}{\sqrt{( {p}^{2} - {ω}^{* 2} ) + 4 {r}^{2} {ω}^{* 2}}}$$

is depending on the coefficient of fading r and on the frequencies p and ω*. It can be seen out of the equation (13) that at r>0 with time t going on, free oscillations described by the summand containing the multiplier e^{-rt}, are quickly fading and disappearing. Only the forced oscillations are remaining having amplitude H and frequency ω*. Difference of phases (φ) of the forced and forcing oscillations are defined by the expressions:

$$sin ϕ = \frac{2 r {ω}^{* 2}}{\sqrt{{( {p}^{2} - {ω}^{* 2} )}^{2} + 4 {r}^{2} {ω}^{* 2}}} , cos ϕ = \frac{{p}^{2} - {ω}^{* 2}}{\sqrt{{( {p}^{2} - {ω}^{* 2} )}^{2} + 4 {r}^{2} {ω}^{* 2}}} .$$

This is why it appears that the forced oscillations of atom nucleuses of the main material in the vicinity of EVCs are happening with the same phase i.e. are not only monochromatic but coherent as well. But atoms of the main material coherently oscillating at the forced frequency ω* are occupying only a certain, limited volume of the material—zone of coherent oscillations, coherency zone. Dimensions of this coherency zone are limited because all atoms of the material cannot realize the coherent oscillations. In the opposite case, it would cause displacement of the mass center of the material by internal forces, which contradicts the major laws of mechanics.

Characteristic dimension of the coherency zone, i.e. coherency length (Λ) may be determined by taking into account that I-oscillations and electrons and phonons linked to them are propagating in the material at the speed of sound (ν_{snd}). It may be ascertained that electrons linked to EVCs obey statistics of Fermi-Dirac, they are able to move inside the material, experience dissipation on dissipation centers, change impulse, loose energy.

Researches of thermal dependence of thermo-EMF (Seebeck effect; EMF means electromotive force) in the semiconductors containing EVCs have showed that the effect of electron drag by phonons (PDE) is dominating over the effect of diffuse (drift) thermo-EMF and appears in the form of narrow bands having Gauss profile located at Debye temperatures of phonons (Tₘ) [28]. Gauss dispersion function θ<<Tₘ. The value of θ is equal to the half-width of PDE band at its half-height. Value θ does not depend on temperature and have the same value for all PDE bands in each material, which matches to the theory of electron-vibration transitions [23-26]. Normally, dispersion θ does not exceed 4 . . . 6 K. In particular, in the silicon having A-centers θ=4.5 K. Width of PDE bands 2θ may be considered as the Debye temperature of phonons by means of which the energy of I-oscillations dissipates at electron-vibration transitions. Considering the value of the Debye temperature 2θ, the dissipation takes place on the long-wave acoustic oscillations. Consequently, energy of I-oscillations gets dissipated on the acoustic phonons having average energy of 2kθ and the part of oscillation energy δ=Tₘ/2θ gets lost in the act of dissipation.

Further, we will use theory of electrons dissipation on acoustic phonons [29], and will determine the average length of their free run:

$$l = {V}_{36} τ = \frac{9 π}{4} \frac{{MV}_{36}^{2} {ℏ}^{4}}{{Ω}_{0} {G}^{2} {m}^{* 2} kT} , \qquad ( 14 )$$

where τ—average time of dissipative quasi-impulse, M—mass of the elementary cell of the material, Ω—volume of the elementary cell of the material, G=(²/2m*)∫|grad(Uₖ)|²d³r—integral over the volume of the elementary cell of the material, Uₖ—amplitude of Bloch electron wave function having the wave vector k, m*—electron effective mass. At quasi-elastic and isotropic dissipation, a part of the dissipated energy in one act of dissipation is δ<<1, and average energy relaxation time is τₑ=τ/δ. In accordance to the expression (14), average length of energy dissipation lₑ=l/δ=lₑ₀/T, where

$${l}_{e 0} = \frac{9 π}{4} \frac{{MV}_{36}^{2} {ℏ}^{4}}{Ω {G}^{2} {m}^{* 2} k δ} ,$$

is not depending on temperature. According to the data regarding the electron drag by acoustic phonons at Debye temperatures of phonons, value δ=2kθ/Tₘ. Besides, the length of free run is not depending on the energy of dissipated electron, which simplifies calculation of the coherency length.

Considering minimum of surface energy, the coherency zone in isotropic material shall have a form of sphere having radius equal to the coherency length Λ. FIG. 8 shows a cross-section of the material by the plane (XY) running through the center of the spherical coherency zone. On FIG. 8 this zone is limited by the dotted circle having radius A. Dissipation of energy of I-oscillation happens in the part of the material adjacent to the coherency zone. This part of the material has a form of spherical layer having thickness equal to the length of free run of electron lₑ and volume Ωₑ. There are Ωₑ/lₑ³ dissipation centers in this spherical layer. During the time τₑ energy equal to 2kθΩ₀/lₑ³ is dissipating on these centers. On the other hand, during the same time τ_{c} the oscillatory energy (E_{osc}) fades e times, i.e. (1−1/e)E_{osc} down. If we will equalize these energies to each other, then we will have the algebraic equation:

$$\frac{4}{2} π [ {( Λ + {l}_{e} )}^{3} - {Λ}^{3} ] \frac{2 k θ}{{l}_{e}^{3}} = ( 1 - \frac{1}{e} ) {E}_{osc} , \qquad ( 15 )$$

which solution

$$Λ = \frac{{l}_{e}}{2} [ - 1 + {( - \frac{1}{3} + \frac{1 - 1 / e}{π} \frac{{E}_{osc}}{2 k θ} )}^{1 / 2} ] \qquad ( 16 )$$

represents the dependence of the coherency length Λ on temperature and on discrete values of oscillatory energy E_{osc}. Possible set of the discrete oscillation energies is wide: 2kθ, kTₘ, ω_{z}, E(v) plus various combinations of these energies with Debye energies of longitude and crosswise material's phonons. This is why coherency length Λ may accept various discrete values at certain temperatures, and between these values it changes in inverse proportion to the temperature T. For example in the silicon having A-centers at E_{osc}=3ω₈=0.66 eV and T=300K, the value Λ10≅mkm, and the size (diameter) of the coherency zone is 2Λ≅20 mkm. It comes out that the coherency zone contains N_{cog}=4πΛ³/3Ω≅2.62·10¹⁸ atoms. But in the case E_{OCS}=2ω₈=0.44 eV then at the same temperature T=300 K the value 2Λ≅16 mkm, and at E_{osc}=ω₈=0.22 eV the value 2Λ≈10 mkm and the coherency zone contains approximately N_{cog}=2.62·10¹⁵ atoms. This way, changing in size of the coherency zone means changing of frequency and phase of I-oscillations of hundreds and even thousands of atoms of the material, and the time of changing of the coherency zone exceeds τₑ. And at this, position of the coherency zone in the material does not change significantly, i.e. coherency zones are poorly mobile. This way, coherency zones are characterized by a single (common) phase of forced oscillations of nucleuses of all atoms, due to which these zones possess zero electric and zero thermal resistances, i.e. they are hyperconductive and superthermoconductive. This conclusion stays in concord with experimental results of measurements of electric conductivity and thermo-conductivity. Actually, appearing of hyperconductivity is accompanied by superthermoconductivity which points at absence of resistance to the movements of not just electrons but of phonons too in the limits of the coherency zones. In the other words, hyperconductivity and superthermoconductivity exist in the coherency zones of the material containing EVCs. Vibrations of atom nucleuses in atoms of the material located outside of the coherency zones either are absent or are not coherent. The material outside of the coherency zones stays in the normal, commonly known condition, and its resistance in feeble fields obeys Ohm law.

Coherency zones of the hyperconductor are practically immobile in the whole volume of the material. By this, hyperconductors are principally different from traditional superconductors, because coherent Cooper pairs in superconductors are mobile and provide superconductivity in large volumes of the material.

Structure of hyperconductor looks like this: numerous spherical coherency zones having micron dimensions having zero electric and thermal resistance are located in a volume of the material and are separated from each other by a regular material (material in a normal, regular state). In such a case, electric and thermal resistance of the material in the whole is defined by resistance of the material outside of coherency zones and it is unquestionably caused by the known mechanisms of dissipation of charge carriers and, possibly, by additional dissipation on the coherency zones and electric joints to the material, i.e. on the border between the material and current electrodes.

In case the coherency zones touch each other and intersect with each other, the combined larger coherency zone appears to be hyperconductive and superthermoconductive.

Extreme dimensions of the coherency zones of the hyperconductor (2Λₘᵢₙ) may be estimated. It comes out of the expression (16) that minimum value of coherency length (Λₘᵢₙ) corresponds to the smallest Debye temperature of oscillations, which for silicon is equal to E_{osc}/k=59.64K. Maximums of the experimental bands of the phenomenon of electron drag by phonons at EVCs in silicon have the smallest temperatures of about 60 K. If the Debye temperature is defined at precision of 0.5 K, then it comes out of the expression (16) that minimal diameter of the coherency zone 2Λₘₘ=109 Å. This way, it looks unlikely that hyperconductivity may exist in thin film materials having thickness not exceeding 2Λₘᵢₙ.

Maximum size of the coherency zone (2Λₘₐₓ) is in great degree determined by the energy of oscillations Eₐₛₑ which, as we could see, can be higher in the semiconductors having wider widths of the prohibited band. As such, in the materials having E_{g}≈2 eV it is possible to have Eₒₛₒ≈2 eV. In this case, at the room temperature, 2Λₘₐₓ≈18 mkm, and at 200K the value 2Λₘₐₓ≈27 . . . 30 mkm. Consequently, coherency zones in typical semiconductors at near-room temperatures may have dimensions in the approximate limits of 15 to 30 microns. For example, in silicon at near-room temperatures it shall be expected to have the value of 2Λₘₐₓ being around 20 mkm.

Accounting that minimum size of coherency zones is close to 100 Å (10 nanometers), and their maximum sizes reach dozens of microns, then hyperconductivity may be reasonably related to non-adiabatic nanoelectronics and non-adiabatic microelectronics.

Concentration of electron-vibration centers. For realizing superconductivity according to the considered mechanism stipulating participation of self oscillations and waves, the material shall be doped with minimum concentration of electron-vibration centers (Nₘᵢₙ). The minimum value of N may be estimated considering that interaction between electron shells of electron-vibration centers is realized by means of acoustic material's phonons and such interaction may appear to be effective at the distance of wavelength of the respective acoustic wave H=ν/F, where ν—wave speed, sound speed and f—wave frequency. In this case N=H⁻³. Minimal frequencies of phonons effectively interacting with EVCs in materials are close to 1.25·10¹⁰ sec⁻¹. Considering the maximum speed of sound to be ν=9.79·10⁵ cm/sec and the mentioned frequency of the elastic wave for acoustic phonons (in silicon), we get Nₘᵢₙ about 2.6·10¹² cm⁻³ (Nₘᵢₙ≈2.6·10¹² cm⁻³). This given estimation of the value N is fair for any material because materials have just slightly different constants of crystalline lattices and sound speeds in them. Analysis of experimental spectrums of photo-conductivity of the silicon samples containing A-centers let to determine the minimal concentration of A-centers (from 2·10¹² cm⁻³ to 3·10¹² cm⁻³) which is able to affect electrical properties of silicon. This way, given estimation of the minimal concentration of electron-vibration centers is conforming the experimental result of Nₘᵢₙ=2·10¹² cm⁻³.

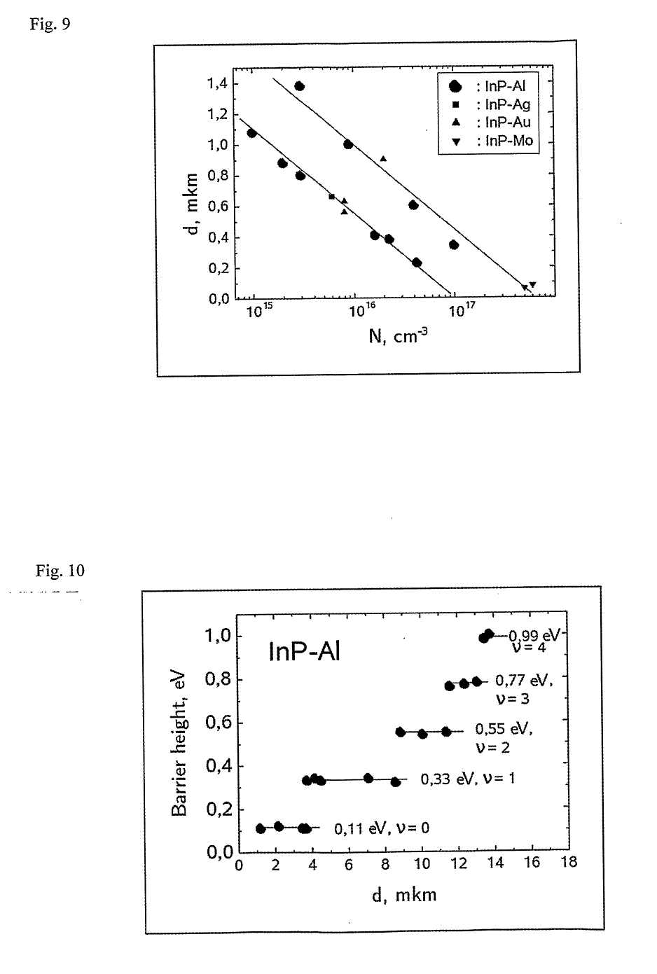

In order to determine the maximum concentration of EVCs, it is reasonable to consider the results of measurements of thickness of the dielectric layer (d) in the experiments of electrons tunneling through a thin dielectric layer in the structure of metal-semiconductor oxide-semiconductor, by measuring the volt-farad parameters [30] depending on concentration of EVCs (N), presented on FIG. 9. On this figure, two inclined straight lined are drawn through the experimental points, related to the processes of tunneling having two different phases of electron waves on the border semiconductor-dielectric. Approximation of the upper line to zero thickness of the dielectric brings the maximum concentration Nₘₐₓ=6·10¹⁷ cm⁻³. This way, a minimal and maximal concentration of EVCs needed for realization of hyperconductivity and superthermoconductivity shall be: Nₘᵢₙ=2·10¹² cm⁻³ and Nₘₐₓ=6·10¹⁷ cm⁻³ respectively.

FIG. 10 shows the experimental results of measurements, using method of volt-farad characteristics, of height of the potential barrier in joints metal-metal oxide-semiconductor depending on thickness of the semiconductor oxide. It can be seen out of this figure that the height of the potential barrier for tunneling is taking discrete values matching the energies of I-oscillations of nucleus in atoms of oxygen, described by the formula of linear harmonic quantum oscillator (10) having various values of oscillation quantum number v=0, 1, 2, 3, 4 and ω₈=0.22 eV. This ascertains us that tunneling of electrons is happening from electron-vibration levels of EVCs formed by oxygen atoms. It can be seen out of FIG. 10 that electrons from the energy level of 0.11 eV participate in tunneling, corresponding to the value v=0, i.e. to <<zero>> I-oscillations of nucleus in atoms of oxygen. This way, it can be seen that tunneling process is quantified, energies of tunneling electrodes are discrete, quantified. And “zero” I-oscillations of EVCs are active, which is prohibited in case of the free quantum linear harmonic oscillator. This proofs that EVCs demonstrate both quantum and classic properties, demonstrate dualism of physical properties. Consequently, I-oscillations of EVCs are not free, EVCs are interacting with electrons, i.e. processes at EVCs are non-adiabatic and they cannot be described in adiabatic approximation of Born-Oppenheimer. These phenomena are relating to the non-adiabatic electronics of materials.

Materials used in the invention. In the present invention any non-degenerate and poorly degenerate semiconductors may be used as the material. Actually, in accordance to the theory, on each EVC in the material, besides I-oscillations of atom nucleuses and phonons, on average S(S≦150) electrons (holes) may exist. In the case when concentration of EVCs is maximal and N═Nₘₐₓ=6·10¹⁷ cm⁻³, concentration of charge carriers localized on EVCs constitutes SNₘₐₓ. Such concentration of electrons (holes) in the material may be provided by means of doping the material with donor (acceptor) dopant having concentration of SNₘₐₓ, which is close to the effective number of states in the permitted energy zone of the semiconductor N_{c} or Nᵥ. According to statistics of electrons and holes in semiconductors, such concentrations of electrons (holes) correspond to the poorly degenerate semiconductor [31]. At lower concentrations of EVCs, concentration of dopant atoms corresponds to non-degenerate semiconductor. This is why in the present invention any non-degenerate and poorly degenerate semiconductors independently of their chemical composition, type of internal structure and type of EVCs may be used as the material between the electrodes.

Experimental researches. First off all, presence of the strong electron-phonon bound at EVCs in a material shall be confirmed. Such interaction manifests itself directly in the phenomenas of electron drag by phonons at Debye temperatures of phonons, in temperature dependences of electric resistance of the material between electrodes, in the infrared optical spectrums.

In the experiments, we were using flat semiconductor wafers having thickness of 200 mkm and containing local electron-vibration centers. We researched samples of GaP having dopings of aluminum GaP(Al) or sulfur GaP(S). Concentration of dopant atoms has been close to 10¹⁵ cm⁻³. These dopants have been chosen because atoms of Al and S have masses exceeding mass of Ga atom, which assists forming of electron-vibration centers and generation of self vibrations and waves. Silicon samples have been researched as well, having dopings of phosphorous (≈5·10¹⁵ cm⁻³) and oxygen (˜10¹⁸ cm⁻³): Si(P,O). Before measurements, the samples have been kept in vacuum for 5 minutes at the temperature T=600 K, after that they have been cooled down to the room temperature during 0.2 minutes for strengthening adhesion of electrodes and forming of electron-vibration centers. Concentration of oxygen has been determined by intensity of characteristic band of IR absorption near 9 mkm. As well, layers of porous silicon (Si*) have been researched having thickness ≈0.3 mkm on silicon n-substrates having specific resistance of 3 Ohm cm. In Si(P,O) and Si* samples electron-vibration centers have been unquestionably formed by atoms of oxygen (A-centers) having constant of electron-phonon bound close to 5.

Temperature dependences of the specific electric resistance p(T) and differential EMF E(T) have been measured in the experimental samples in order to reveal a strong electron-phonon bound in the temperature band of 77K to 700K. Temperature difference of electrodes during measuring E(T) has been not exceeding 3K±0.2K, and the field strength during measurement of ρ(T) has been not exceeding 1 V/cm. As well, variations of IR reflection spectrums caused by dopings Al and S in GaP in the optical band of 15 mkm (83 meV) to 2 mkm (620 meV) at 300K have been measured in order to reveal electron-vibration processes. Falling angle of non-polarized light beam on the sample's surface has been set up to 45°.

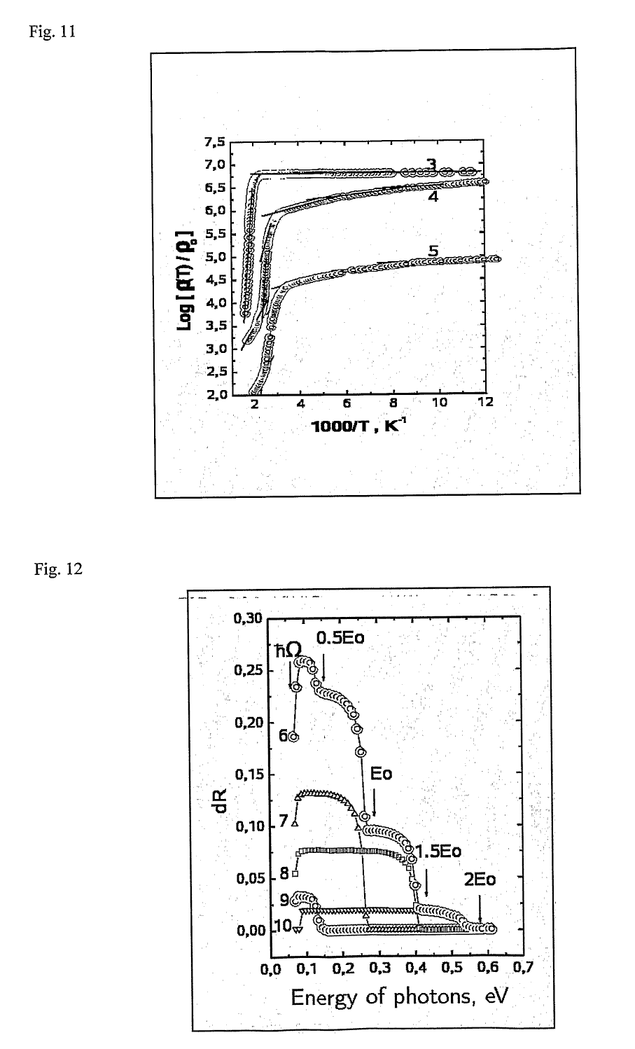

Typical temperature dependences of the specific resistance of GaP(Al) samples—curve 4 and of GaP(S)—curve 5 in semi-logarithmic coordinates Log [ρ(T)/ρₒ] from 10³/T are presented on FIG. 11. The value ρₒ is the constant and it is chosen for each curve in such a way that the curve would be conveniently located on the drawing. Curve 3 on FIG. 11 represents the thermal dependence of the specific resistance of GaP sample having no dopings. These curves are piecewise linear. Tangents to the linear pieces of the curves are outlining these pieces having particular inclinations relatively to the coordinate axes related to the particular activation energies (Eₙ). Values of Eₙ, measured at temperatures below 330K are put into the table 1 where lines holding the activation energies matching known phonon energies in GaP are marked with asterisks [32]. Energies of these phonons are given in the central column of the Table 1. Activation energies of GaP(Al) and GaP(S) samples measured at temperatures below 330K, are shown in Table 2, which holds as well the self oscillation energies of the doping atoms, calculated using formula (10) accounting the value of elementary quant of I-vibrations Eₒ=0.283 eV for Aluminum atom and E₀=0.301 for sulphur atom. Curve 3 on FIG. 11 reflects the activation energies of Eₐ≅0.7 meV at temperatures below 330K, but at temperatures above 330K the value of Eₐ is close to the prohibited band of GaP (2.4 eV). Curves 4 and 5 on FIG. 11 may be described by a number of activation energies. The respective values of Eₐ are put into the Table 1 and Table 2 and may be explained in different ways. The values of Eₐ contained in the strings of Table 1 marked with asterisks are close to the energies of crystalline phonons in GaP that intensively interact with electron-vibration centers. Values of these phonons are given in the middle column of Table 1.

Experimental dependencies 4 and 5 cannot be explained by dissipation of charge carriers by phonons because such dissipation is able to produce the effect opposite to the observed decreasing of the specific resistance when temperature is rising. We link the respective activation energies to the generation of free charge carriers from electron-vibration levels of local centers formed by α-type I-vibrations of Aluminum and Sulfur atoms. Other energies in Table 1 may presumably be explained by generation of free charge carriers from electron-vibration levels formed by self oscillations of β- and γ-types of doping aluminum and sulfur atoms and probably by combinations of such vibrations with crystalline phonons.

It can be seen out of Table 2 that activation energies of the samples having each type of doping may be split into two groups related to the two right columns of Table 2.

One group consists of the activation energies described by the formula of quantum harmonic oscillator.

TABLE 1
Activation energies of specific resistance of the samples GaP(Al) and GaP(S)
measured at temperatures below 330K

| GaP(Al) samples Nos.: | | | | | Phonons in | GaP(S) samples Nos.: | | | | |
|---|---|---|---|---|---|---|---|---|---|---|
| 1 | 2 | 3 | 4 | 5 | GaP (meV) | 6 | 7 | 8 | 9 | 10 |
| 8.1 | — | — | 7.2 | 8.0 | — | — | — | — | — | — |
| *15.0 | — | — | 14.8 | 14.5 | 14.25 | 15.0 | 14.8 | — | — | 14.3 |
| *24.5 | — | — | — | 25.0 | 24.42 | 24.0 | — | 24.6 | — | — |
| — | 35.0 | — | — | — | — | — | — | — | 28.0 | 28.0 |
| *45.0 | — | — | — | 44.6 | 44.75 | — | 42.0 | — | — | — |
| * — | — | 49.0 | 48.0 | — | 47.00 | 47.0 | — | — | — | — |
| 75.0 | — | 83.0 | — | — | — | — | — | 70.0 | — | — |

These activation energies are linked to α-type of self-vibrations of the doping atoms and relate to the transitions from vibration states having v=0, 1, 2, . . . into the minimum of oscillatory potential, where oscillation energy is zero. For a free harmonic oscillator such transitions are prohibited, but they are possible for non-free as well as for classic oscillator. Consequently, self oscillations of doping atoms demonstrate dualism of properties, which may be explained by their interaction with electrons (by means of phonon exchange).

Another group of energies in Table 2 consists of the activation energies divisible by E₀. This group of energies is as well linked to the self α-type I-vibrations of doping atoms, EVCs, and correspond to the transitions between various oscillation levels, between levels having various values of v. The value of E₀ is common for both groups- of energies. Consequently, both energy groups belong to the same type of centers demonstrating quantum and classic properties (dualism of physical properties) under the conditions of strong electron-phonon interaction.

TABLE 2
Activation energies (eV) of specific resistance of GaP(Al) and
GaP(S) samples measured at temperatures above 330K

| | | | | | Calculated by | Multiplicity |
|---|---|---|---|---|---|---|
| | | | | | formula (7) | E₀, eV |
| Activation energies (eV) of GaP(Al) | | | | | | |
| samples, Nos.: | | | | | | |
| 1 | 2 | 3 | 4 | 5 | — | — |
| 0.14 | 0.14 | 0.14 | 0.138 | 0.137 | 0.1415 (ν = 0) | — |
| 0.28 | 0.29 | 0.29 | 0.28 | 0.28 | — | E₀ = 0.283 |
| 0.42 | 0.42 | 0.43 | 0.42 | 0.43 | 0.4245 (ν = 1) | — |
| — | 0.57 | — | 0.56 | 0.58 | — | 2E₀ |
| 0.71 | — | 0.72 | — | — | 0.7075 (ν = 2) | — |
| — | — | 0.85 | — | — | — | 3E₀ |
| — | 0.97 | — | — | — | 0.9905 (ν = 3) | — |
| 1.1 | — | — | — | 1.11 | — | 4E₀ |
| Activation energies (eV) of GaP(S) | | | | | | |
| samples, Nos.: | | | | | — | — |
| 6 | 7 | 8 | 9 | 10 | — | — |
| 0.15 | 0.15 | 0.15 | 0.15 | 0.15 | 0.1505 (ν = 0) | — |
| 0.3 | 0.29 | 0.3 | 0.3 | 0.31 | — | E₀ = 0.301 |
| — | — | — | — | — | 0.4515 (ν = 1) | |
| 0.6 | — | 0.6 | 0.61 | — | — | 2E₀ |
| — | — | — | — | 0.74 | 0.7525 (ν = 2) | — |
| — | — | 0.92 | — | — | — | 3E₀ |
| 1.03 | — | — | — | — | 1.0500 (ν = 3) | — |

Researches of the infrared reflection coefficient (R) have similarly confirmed presence of self oscillations in GaP(Al) and GaP(S) samples and their intensive interaction with electrons and crystalline phonons. Changes of IR reflection spectrum (dR) caused by doping atoms, represented by curve 6 on FIG. 12, have been split into components in accordance to the theory [33, 34] accounting shares of various charged oscillators existing in various vibration states. These components are numbered on FIG. 12 with numbers 7, 8, 9, 10. Each component adds its share into the coefficient of reflection R reaching its maximum at optical frequencies (ω) satisfying the conditions: ωₚ>ω>Ω, where Ω—oscillator's frequency and ωₚ—frequency of elastic vibrations of the material. Minimum of dR is located near ωₚ. Concord between the experimental (6) and the sum of calculated components of the spectrum 7, 8, 9, 10 is reached in case when energies ωₚ match energies of (α-type) self-vibrations of aluminum atoms: 0.5E₀, E₀, 1.5E₀, 2E₀. Two of these energies match the ones calculated using formula of linear harmonic oscillator (10) if the elementary quant of the oscillations is equal to the quant of I-vibrations of nucleus in aluminum atom E₀=0.283 eV and v=0 of 1, and two others are the multiples of the same value E₀=0.283 eV. The reflection spectrum of GaP(S) is well described in the framework of the oscillatory model too [33, 34] when the elementary quant of oscillations is equal to the quant of I-vibrations of nucleus in sulfur atom E₀=0.301 eV. Energies ωₚ for both types of dopings (Al, S) may be linked to the γ-type of self oscillations of Al (61.1 meV) and S (65.0 meV). Fading of self oscillators is quite strong (η/Ω=0.09, where η—coefficient of fading) and it is corresponding to the strong bound of EVCs with electrons by means of phonons. This way, electron-vibration centers formed by doping atoms of Al an S in GaP demonstrate dualism of optical properties. These properties are defined by interaction of I-vibrations of doping atoms, material's phonons, electrons (holes) with each other. This confirms existence of strong electron-phonon bound in GaP. In the other researched materials similar results have been received. This way, optical researches have confirmed presence of strong electron-phonon bound on EVCs in the materials.

The best concord between calculated and experimental reflection spectrums is achieved in the case when the dielectric permittivity coefficient (δ≅2) is small comparing to the high frequency dielectric permittivity coefficient of GaP (∈=8.457) [35]. It looks like the changed value of the dielectric permittivity shall be related to the local centers where optical transitions are happening, and not to the whole volume of the material. At the same time, trapping cross-section of the electron-vibration center for photons may be defined by the wavelength of material's phonon interacting with the center.

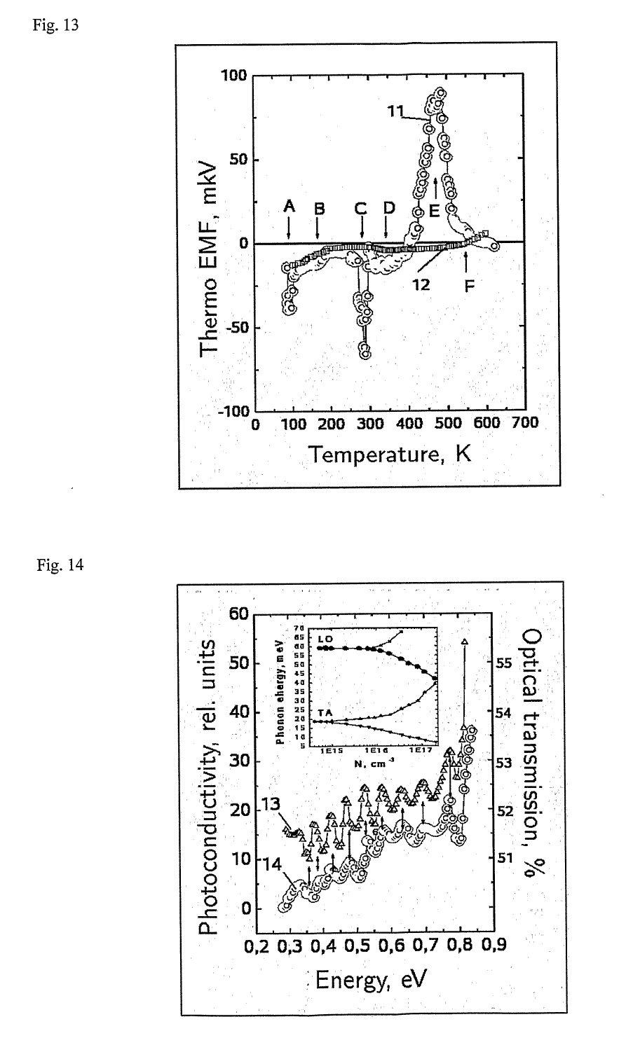

Self-oscillations of EVCs may propagate in materials in the form of waves of I-oscillations, when the electron-vibration states are migrating in the material from one EVC to another EVC. I-oscillations of atoms of the main material and waves of such oscillations of atoms of the main material may as well exist in materials. Waves of I-oscillations, material's phonons and electrons (holes) effectively interact with each other, form specific system of particles and quasi-particles having their own physical rules and, at certain conditions, they are able to cause electric currents not linked to motion of free electrons and holes in the material. This is confirmed by specific features of the experimental temperature dependences of differential thermo-EMF E(T). Curve 11 on FIG. 13 represents a typical temperature dependence of thermo-EMF E(T) for the sample of GaP(S). Curve 12 on FIG. 13 is a typical temperature dependence of thermo-EMF E(T) for the sample of GaP without dopings and defects and may be explained by conductivity of the sample being close to the inherent conductivity, i.e. by means of free electrons and holes. Curve 11 contains pikes, marked with arrows, and Latin letters. Polarity of these pikes is in concord with polarity of the differential thermo-EMF. We are explaining these pikes by the phenomena of electrons (holes) drag by phonons. Pikes A, B, C, F are located at Debye temperatures of crystalline phonons in GaP:95K (TA; 8.2 meV); 168K (TA; 14.25 meV); 288K (LA; 24.42 meV); 542K (LO; 44.75 meV). The wide pike D (≅345K) and the pike E (≅475 K) may be explained by combination of crystalline phonons: (TA+TA; 28.6 meV) and (TA+LA; 38.67 meV). Dependence of E(T) for GaP(Al) is similar to the curve 11 on FIG. 13.

This way, researches of temperature dependences of the specific resistance and of the thermo-EMF as well of IR reflection have showed that I-vibrations of aluminum and sulfur atoms in GaP are actively interacting with crystalline phonons and with electrons (holes), and by this provide a strong electron-phonon bound which is sufficient for realizing of electrons (holes) drag by phonons at relatively high temperatures located at a few hundred degrees of the absolute temperature scale.

Experimental researches of silicon (Si) samples.

Measurements of the temperature dependences of the thermo-EMF and of the specific resistance have been conducted using industrial flat samples of monocrystal silicon KEF4.5 having thickness of W=200 . . . 300 mkm. It is known that silicon contains oxygen impurity which is electrically inactive but may be revealed though the specific absorption of IR radiation having wavelengths of 9 . . . 10 mkm. Basing on IR absorption in the said spectrum band, the experimental samples were containing oxygen in concentration of about 10¹⁸ cm⁻³.

As the result of certain treatments (radiation raying, thermal treatment, covering with metal and dielectric layers), the alloy atoms of oxygen in silicon are joining with vacancies and forming A-centers [36]. A-centers are the electron-vibration centers having the large constant of electron-phonon bound S≈5 while in the defectless silicon the value of S≈0.25. Exactly A-centers in silicon have been used by us for realization of hyperconductivity and superthermoconductivity at high temperatures.

Experimental polished silicon wafers have been subjected to the thermal oxidizing using the industrial technology in dry oxygen until forming-of- oxide film having thickness of ˜0.05 mkm. Then this oxide film has been etched away and aluminum electrodes have been formed on the flat surface by means of thermal evaporation in vacuum; the gap between the electrodes D has been set up from 20 mkm to 50 mkm. A-centers have been inputted into the samples by means of their irradiation with fast electrons having energies of ≈1 MeV and current having density of 1 mA/cm² during 1 . . . 2 minutes. Volt-farad characteristics of the treated samples have been measured, as well as differential thermo-EMF and temperature dependences of electric resistance in the material between the electrodes.

Spectrums of photoconductivity and IR absorption related to A-center is silicon monocrystals contain oscillations [37]. Period of these oscillations matches the energy of characteristic phonons in silicon. FIG. 14 shows spectrums of photoconductivity (σ), curve 13 and spectrum of optical passing through (P), curve 14, of monocrystal silicon containing EVCs, A-centers having concentration of about 10¹⁴ cm⁻³. Both these curves are non-monotonous and contain a number of extremums located at the same photon energies. Vertical bidirectional arrows mark extremums of the curves laying on the same energies. Energies of the adjacent extremums differ by the energy of acoustic phonon in silicon, which permits to definitely link the extremums existing in the spectrums to the crystalline phonons participating in electron transitions under the influence of phonons. This ensures us that the electron transitions are the electron-vibration transitions from the valence band onto one of the energy levels of A-centers (E_{c}-0.22 eV). Similar spectrums of photoconductivity and optical passing through, oscillating with energies of phonons, have been measured in silicon samples having various crystallographic orientations and at various polarizations of IR radiation. It has been established that the crosswise acoustic phonons having the following energies and wave vectors directed along: (111)-16 meV, (110)-19 meV, (100)-23 meV participate in such spectrums. These experimental data are well matching the energies of characteristic phonons in silicon [38] and permit to judge about presence of the strong electron-phonon bound on A-centers in silicon. It can be seen out of FIG. 14 that increasing of optical passing through related to decreasing of optical absorption causes rise of photoconductivity, i.e. in this case photoconductivity is negative which is generally typical for EVCs. This may be explained by the fact that I-vibrations of A-centers, excited by means of energy of optical quant, cause localization of electrons and holes on A-centers, i.e. may be explained by the strong electron-phonon bound.

Data have being received out of analysis of electron-vibration spectrums regarding energies of phonons interacting with electrons on A-centers, and regarding influence of interaction between A-centers over the energy of phonons. In the insert to the FIG. 14, the experimental data are presented showing the changing of energies of the acoustic and optical phonons at changing of concentrations of A-centers in the material. At changing of concentration of A-centers (N), average distance between them (R) varies and it is equal to N^{-1/3}. At the elastic interaction between the centers in three directions (coordinates), energies of phonons, according to the theory, are changing by the law of R⁻⁷, at interaction in two directions they change by the law of R⁻⁵, and in the single-dimensional interaction they change by the law of R⁻³. A particular conclusion comes out of the experimental data, saying that the elastic interactions of EVCs in materials (in this case, interactions of A-centers with each other) are single-dimensional and their I-oscillations correspond to oscillations of quantum harmonic linear oscillator. Because of this reason, inter-center electron-vibration transitions in materials are the single-dimensional transitions. Constant of electron-phonon bound S≈5 at the low concentrations of EVCs. Increasing of the concentration of EVCs up to 10¹⁷ cm⁻³ will cause decreasing of constant S down to 1.

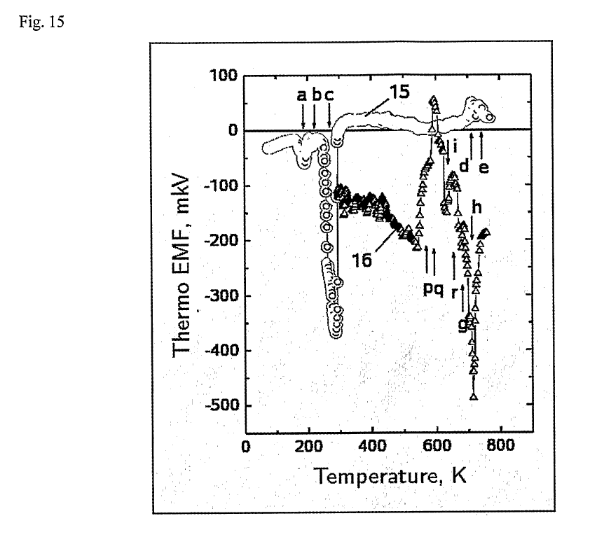

Curve 15 on FIG. 15 is a typical temperature dependence of the thermo-EMF E(T) for the samples of silicon doped by phosphorous and oxygen atoms—Si(P,O). This curve contains pikes, marked by arrows and letters a, b, c, d, e. Polarities of these pikes stay in concord with polarity of differential thermo-EMF. Pikes a, b, c are located at Debye temperatures of the acoustic phonons having wave vector oriented along particular directions [38]:<111>:200.4K (16.7 meV); <110>: 214.8K (17.9 meV); <100>:252K (21.0 meV). We explain these pikes by electrons drag by phonons. We link pikes d and e with the drag of electrons by TO phonons of silicon. Curve 16 on FIG. 15 represents the dependence of E(T) in porous silicon (Si*), and it contains pikes p, q, r, g, h having various polarities. Temperatures of these pikes are matching Debye temperatures of phonons in critical points of Brillouin zone of silicon: L(W)—551K (45.9 meV); L(L)—606K (50.5 meV); TO(X)—683K (56.9 meV); TO(L)—712K (60.9 meV) respectively. Pikes p, q, r, g are linked to holes drag by the said phonons, and pike h is linked to electrons drag by phonons.

Phenomenon of electron drag by phonons (PDE) has been observed earlier at the temperatures below 70K as the additional share into the differential EMF only in Germanium (Ge) monocrystals. Absence of PDE at higher temperatures have been earlier explained by insufficiently strong electron-phonon bound. The same opinion stays until nowadays. Nevertheless, monotonous temperature dependence of differential thermo-EMF in bundles of carbon nanotubes have been presumably explained by the share of PDE at temperatures from 4.2K to 300K [39]. Narrow pikes of PDE have been found in carbon nanotube films on substrates at temperatures of up to 600K. PDE in carbon nanotube films on substrates is caused by the interaction of electrons in the film with phonons of the substrate by means of a-inherent—oscillations of carbon atoms (E₀=0.25 eV) and oxygen atoms (E₀=0.22 eV). This way, phenomena of electron drag by phonons at Debye temperatures of phonons of the material or of the substrate is the real phenomenon in various materials at high temperatures. Presence of this effect proofs existence of elastic waves of I-oscillations and of the strong electron-phonon bound linked to EVCs, and the cause of them is by itself the phenomena of electron drag by phonons at Debye temperatures of phonons.

The phenomena of electrons (holes) drag by phonons at Debye temperatures of phonons of a few hundreds degrees in any materials containing EVCs manifests itself exclusively due to the strong electron-phonon bound which exists due to electron-phonon centers (EVCs) providing a strong interaction between self oscillations, electrons (holes) and material's phonons.

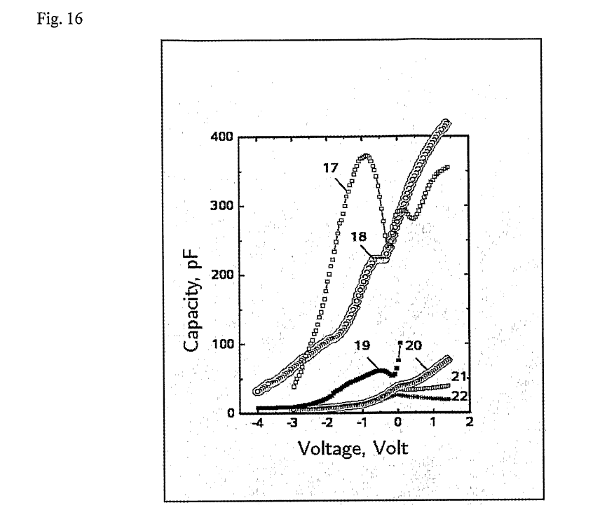

FIG. 16 shows typical volt-farad (CV) characteristics of contacts Si—Al having surface of 4.9·10⁻⁴ cm², measured at various frequencies at the room temperature. Experimental C-V curves are frequency dependent and at each frequency the value of capacity changes non-monotonously at increasing of reverse bias, which does not correspond to the traditional theory of capacity of defectless metal-semiconductor joint. On FIG. 16 curve 17 is measured at the frequency of 0.2 MHz, curve 18—0.5 MHz, curve 19—1 MHz, curve 20—5 MHz, curve 21—10 MHz and curve 22 is measured at the frequency of 20 MHz. Frequency dependence of the C-V curves is defined by A-centers present in the samples. It has been established that minimum of the capacity is reached at the frequency of acousto-electric synchronism (≈23 MHz at W=200 mkm for Si), when a standing wave appears in the semiconductor plate having thickness W, and period of an external radio signal applied to the contact matches the time of sound traveling to the opposite side of the plate and back. Analysis of such C-V curves requires a new physical model of joints.

Experimental C-V curves presented on FIG. 16 may be described by the known dependence of the contact capacity (C) on the applied bias voltage (V), putting that the effective area of the contact (Σ) depends on voltage: Σ=Σ(V). Such dependence is matched by the material model accounting presence of small sized droplets having high electro conductivity in the semiconductor under the contact, which, by our opinion, are the coherency zones and posses superconductive properties. Actually, as the electric field penetrates into the material at increasing of reverse bias voltage, the border of depleted zone reaches some of these droplets and the area of equipotential surface matching the border of the depleted zone increases. Equipotential of the border of the depleted zone in the material under the electrode will run now by the surface of conductive droplets and the effective area of the contact strongly increases. As the result, differential capacity of the contact shall grow up respectively. The experiment shows a smooth rise of the capacity at exceeding of some bias voltage, which may be explained by volume distribution of the droplets having small size, which are successively reached the equipotential of the border of the depleted zone. Non-monotonous dependence of the capacity C on the bias voltage V in this model may be linked to the presence of a number of droplet's layers. These layers, as it is known, actually do exist in such and similar structures [40, 41]. Besides, periodicity of the layers as well depends on the voltage applied to the contact and on the frequency of radio signals which as well brings in its own share into the frequency dependence of C-V curves. Respective model of the contact letting to describe the frequency dependence of capacity contains the coherency zones of small size located under the field electrode in the semiconductor. These zones are distributed randomly and are grouped in layers parallel to the field electrode. It shall be noticed that experimental C-V curves may be explained exactly by the discrete structure of the layers, their forming from small parts, form coherency zones. Monolithic layers are useless because in this case the value of differential capacity cannot increase or decrease relatively to the capacity of the depleted zone of the semiconductor at increasing of negative bias on the contact, and in this case capacity variation observed in the experiments cannot be explained.

Presence of conductive, hyperconductive droplets in the semiconductor under the field electrode stay quite in concord with the possibility of forming of coherency zones having characteristic dimension of 2Λ, and experimentally received frequency dependence of the differential capacity of semiconductor contacts confirms presence of such zones in the samples having electron-vibration A-centers. In this case, in order to realize hyperconductivity between the electrodes, it is sufficient to set the distance (D) between them in such a way so the condition “D less than 2Λ” would be fulfilled. In this case, the coherency zone will close the electrodes and, by this, the hyperconductivity will exist between the electrodes.

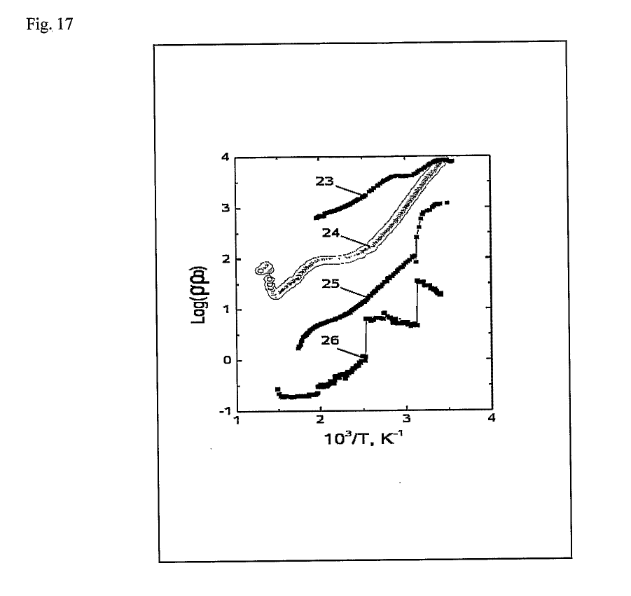

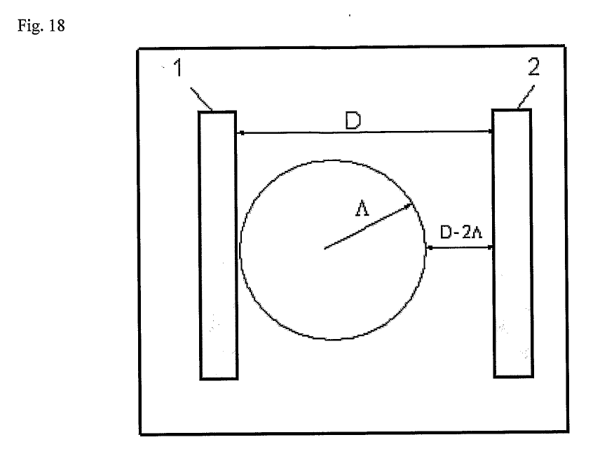

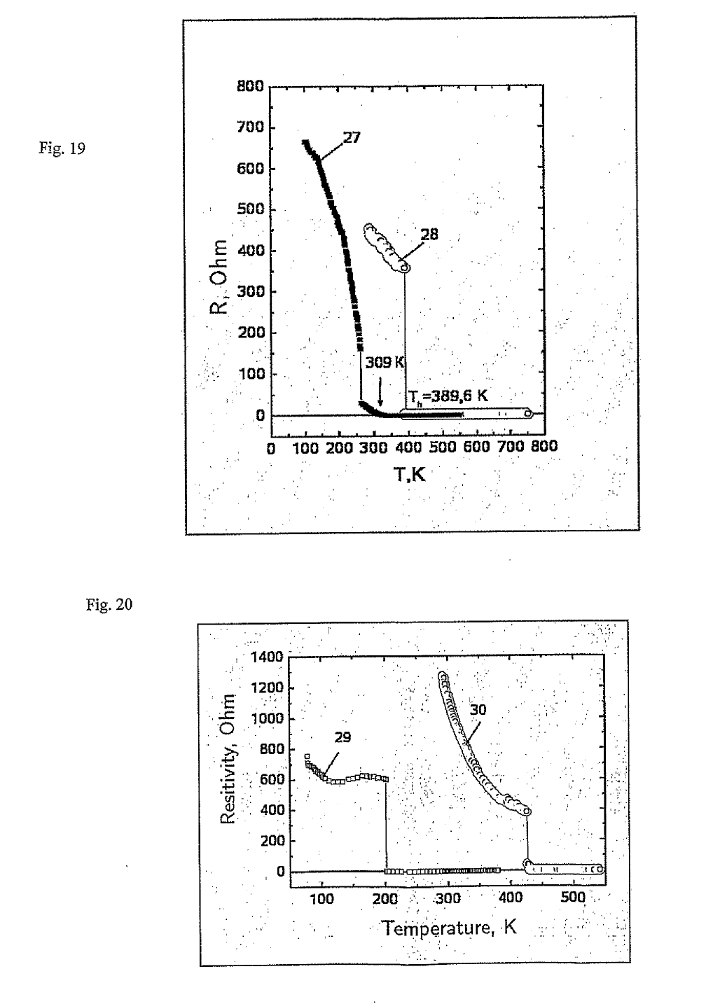

FIG. 17 shows the experimental temperature dependences of specific resistance of the material between the electrodes on the silicon samples having different distances between the electrodes D. Curve 23 corresponds to D=50 mkm, curve 24 to D=40 mkm, curve 25 to D=30 mkm, curve 26 to D=22 mkm. Analysis of these curves shows that as the distance D decreases at certain temperatures, sharp dropdowns of specific resistance (ρ) appear on the curves, which we link to the forming of coherency zones and changing of their dimensions. At D>20 mkm the resistance between the contacts does not reach zero at heating up of the material but runs towards saturation or even grows at temperature rising above 500K because 2Λ<D. As the value of 2Λ does not reach D, then the measured specific resistance (ρ) does not reach zero value. Actually, at D>2Λ the coherency zone occupies only a part of the material between the electrodes, as it can be seen on FIG. 18. FIG. 18 shows the cross-section of the researched sample having electrodes 1 and 2 divided by the distance D>2Λ between them. Cross-section of the spherical coherency zone is shown by the dotted line having radius Λ. A layer of the material between the coherency zone and electrode 2 is located on the current's path between the electrodes and it possesses a finite, nonzero resistance. Because of this, the electric resistance of the material between the electrodes does not reach zero value, because it is limited by resistance of the layer of the material having thickness of D−2Λ. In this layer having thickness of D−2Λ electrons are experiencing dissipation as in a regular material. According to formula (16), Λ takes discrete values corresponding to the discrete values of oscillation energies that are reached at certain temperatures of the material. Exactly at these temperatures sharp changes of the material's resistance happen. As the temperature increases, transition happens onto another, higher value of the oscillation energy E_{osc}, and Λ tales a new, higher discrete value and, as the result, the resistance of the material between the electrodes drops down. This behavior of the resistance may be seen on curves 25 and 26 presented on FIG. 17 and on the curve 27, FIG. 19. In such states, hyperconductivity and superthermoconductivity exist in the coherency zones and manifest themselves, in particular, in repulsion of the silicon material having the electrodes out of a magnet similarly to the repulsion of superconductors known as Meissner phenomenon.

Between the temperatures of sharp jumps of Λ according to formula (16) the value of Λ changes inversely proportional to the temperature—decreases as the temperature grows. Accordingly, thickness (D−2Λ) of the material layer between the coherency zone and the electrode shown on FIG. 18 increases, and due to this the resistance of the material between the electrodes increases. Such a behavior of the resistance of the material between the electrodes may be seen on curve 26 shown on FIG. 17. In the case if thickness of the layer of the material between the coherency zone and the electrode (D−2Λ) becomes tunnel-thin, then tunneling electron-vibration transitions begin to happen between the coherency zone and the electrode, which can be seen on curves 25 and 26, FIG. 17, at high temperatures. In this case, the resistance variation of the material layer having thickness D−2Λ at heating up does not depend on dissipation on phonons and the resistance of the material between the electrodes goes down, which can be seen on curve 27, FIG. 19. This way, the temperature dependence of the resistance of the material between the electrodes at D>2Λ is matching pretty well with calculations and with specifics of temperature behavior of the coherency length.

At D≦2Λ, coherency zone covers the whole distance in the material between the electrodes and hyperconductivity with superthermoconductivity get reached between the electrodes. FIG. 19 shows the typical temperature dependences of the specific resistance of silicon between the electrodes separated by the gap D=19 mkm (curve 27) and D=20 mkm (curve 28): Curve 27 shows that at the temperature above Tₕ=309K resistance of the material between the electrodes of the sample has dropped down to zero, i.e. hyperconductive state has been reached between the contacts: the zone of coherency have covered all the material between the electrodes, the value of 2Λ became not less than D. It can be seen out of the curve 28, FIG. 19, that the temperature of hyperconductivity transition Tₕ=389.6 K and the state having zero electric and zero thermal resistances is reached at the temperatures exceeding Tₕ.

This shows a principal possibility to realize hyperconductivity and superthermoconductivity in material between electrodes at temperatures exceeding the near-room temperature, defined by electron-vibration centers, and experimental realization of these phenomena has been done. Rising of the temperature of the experimental silicon samples up to 780K in nitrogen atmosphere at normal pressure did not corrupt hyperconductivity and superthermoconductivity, which concords with the opinion, based on calculations, regarding hyperconductivity and superthermoconductivity staying up to melting temperatures of the metal contacts and or of the material itself, and even in melted material. Now it can be seen that hyperconductivity and superthermoconductivity represent a specific dynamic state of the material, which existence is determined by self-oscillations of atomic nucleuses in atoms of materials.

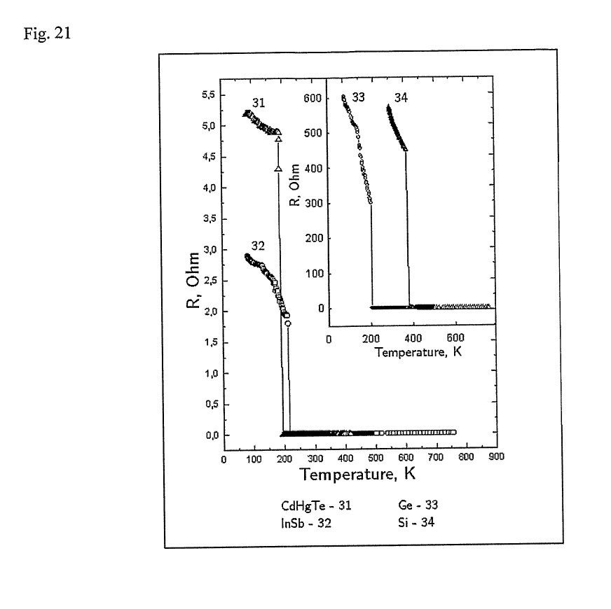

Similar phenomenon consisting in rising of hyperconductivity and superthermoconductivity in the material between the electrodes may be observed as well in samples based on any other semiconductors. When heating the material up to Tₕ and above Tₕ at D≦2Λ, hyperconductivity and superthermoconductivity appears in the materials between the electrodes. FIG. 20 shows the typical temperature dependences of resistance of Ge (curve 29) and GaAs (curve 30) between the electrodes at D=19 mkm<2Λ. For the dependence 29, the value of Tₕ is close to 200K and for the dependence 30 the value of Tₕ≈432K. FIG. 21 shows characteristic temperature dependences of resistance of narrow-gap materials CdHgTe (curve 31) and InSb (curve 32) having D=18 mkm<2Λ. In the insert to the FIG. 21 the typical temperature dependences for Ge (curve 33) and Si (curve 34) having D=19 mkm<2Λ are presented. For the curve 31 the value of Tₕ is close to 195K, for the curve 32 Tₕ≈215K, for the curve 33 Tₕ≈200K and for the curve 34 Tₕ≈290K. In all the materials at temperatures above Tₕ at D<2Λ appears hyperconductivity and superthermoconductivity. This way, hyperconductivity and superthermoconductivity in the materials between the electrodes is reachable and exists at temperatures above the temperature of hyperconductivity transition Tₕ independently of the sort of atoms of the main material, of type the of material lattice or of the internal structure of the material and of the width of prohibited band of the material, in case if distance between the electrodes D≦2Λ.

Because minimal size of the coherency zone in various materials being 2Λₘᵢₙ≅10 nanometers and maximum size of the coherency zone being 2Λₘₐₓ≅30 microns have been established, it can be certainly assorted that in order to realize hyperconductivity and superthermoconductivity in the material between the electrodes the distance between the electrodes D in the material shall be chosen in the limits between its minimal value of D_{MIN}≅2Λₘᵢₙ=10 nanometers and its maximum value of D_{MAX}=2Λₘₐₓ=30 microns.

Superthermoconductivity. It has been as well established that appearance of hyperconductivity is accompanied by a giant increase of thermo conductivity between the electrodes. According to experimental data, the value of thermo conductivity coefficient rises more than 10⁵ times. Here we deal with a new effect (phenomenon) of superthermoconductivity accompanying the technical effect (phenomenon) of hyperconductivity.

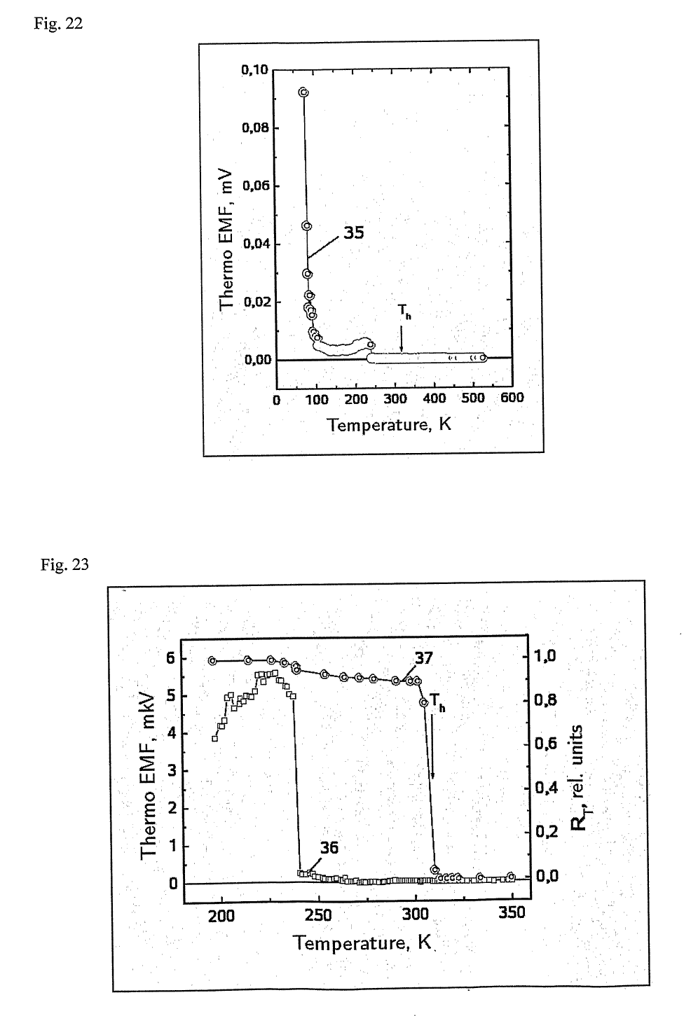

Near the temperatures of sharp dropdown of the specific resistance, differential thermo-EMF E(T) drops down as well. FIG. 22 shows the temperature dependence of the thermo-EMF E(T) (curve 35) for the silicon sample having D=19 mkm on which the dependence 27 having Tₕ=309K have been measured, shown on FIG. 19. FIG. 22 shows that during heating the material between the electrodes up, the thermo-EMF decreases non-monotonously; near the temperature of Tₕ≈309K it reaches zero value and stays zero at temperatures above Tₕ. Such a behavior of the thermo-EMF is typical for all materials between the electrodes. At heating some samples up, decreasing of the thermo-EMF is going non-monotonously at shifting polarity as well, and at temperatures above Tₕ it is steadily equal to zero. Researches have shown that turning of the thermo-EMF to zero at the temperature Tₕ and higher is caused by sharp rising of thermo conductivity of the material between the electrodes at temperature near Tₕ. Thermal resistance of the material between the electrodes here drops down 5 . . . 6 order, practically down to zero value. This is how the phenomenon of superthermoconductivity appears accompanying hyperconductivity. On FIG. 23 curve 36 is the fragment of the temperature dependence of the material resistance between the electrodes of silicon sample 27, presented on FIG. 19, for which Tₕ=309K. Curve 37 is a temperature dependence of the thermal resistance (R_{T}) of the same sample. It reaches zero value near the temperature Tₕ. The values of electric and thermal resistances of the material between the electrodes simultaneously turning into zero is characteristic and represents the technical phenomenon of superthermoconductivity accompanying hyperconductivity.

This is why hyperconductive materials may be used as heat conductors having small, zero, thermal resistance, and possess a significant advantage comparing to the known heat conductors. As it is known, oriented plates of diamond are used in microelectronics for providing a low thermal resistance, 6 times lower than thermal resistance of copper conductor. It is obvious that by cost and by thermal resistance diamond conductors are loosing to the hyperconductors used as heat conductors.

Contacts to the material. Presence of EVCs and self oscillations of these centers is not a sufficient condition for realizing of hyperconductivity and superthermoconductivity. Due to interaction of electron shells with each other, their displacements may be coherent within the coherency zone having characteristic size Λ. The value of Λ may exceed dozens of constants of material, crystalline lattice. Coherency zones are the superconductive zones of the crystal. But changing of the wave function, switching phases of the function happen on the border of the coherency zone, which is equivalent to the process of dissipation of electrons and resists propagation of hyperconductivity and superthermoconductivity over the whole volume of the material in the vicinity of the coherency zone having characteristic dimensions equal to the doubled coherency length 2Λ. At this, the coherency zone is a kind of “bound” to motionless electron-vibration centers and cannot move quickly inside the material and, consequently, not the whole volume of the material becomes superconductive. This is why if we will setup the electrodes on the distance D not exceeding Λ from each other, then superconductive coherency zones will close the electrodes and hyperconductivity together with superthermoconductivity will appear between them. But in the case if D is exceeding Λ, then dissipation of electrons on the border of the coherency zone will resist superconductive current running between the electrodes. Consequently, the necessary (but not the only) condition for realizing of superconductivity in the material between the electrodes is the condition of D being less than Λ (D<Λ).

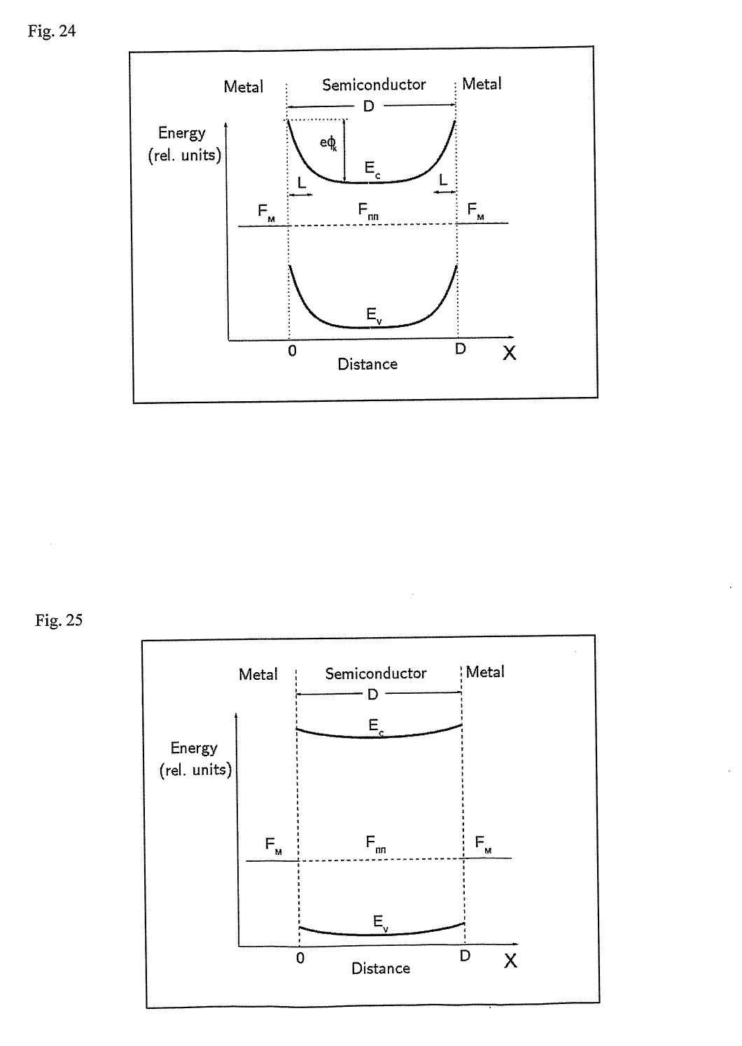

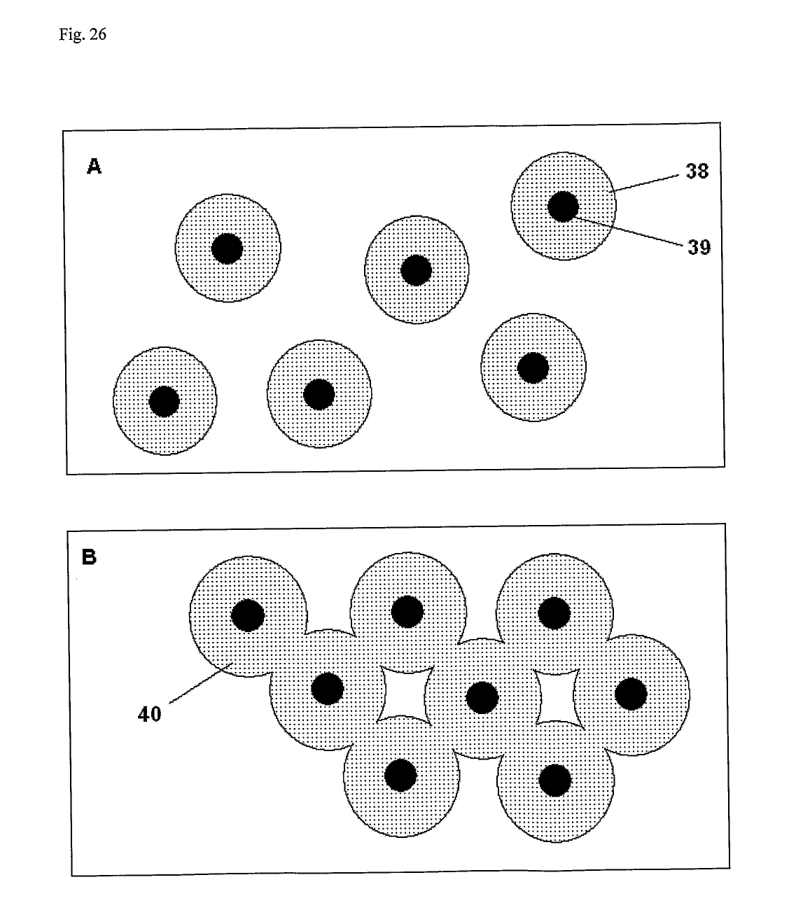

One more condition is important. It may be seen by considering physical processes near the contacts. FIG. 24 shows the energy band diagram of the structure having oppositely set contacts metal-semiconductor (Schottky joints) in the state of thermodynamic equilibrium. Here Fₘ and Fₛₑₘ define Fermi levels in the metal and in the semiconductor respectively. The semiconductor has the electron type of conductivity and its Fermi level Fₛₑₘ is close to the bottom of conductivity band E_{c}. Eᵥ—ceiling of valence band, and width of prohibited band of the semiconductor is E_{g}=E_{c}−Eᵥ. Height of the built-in potential barrier e φₖ is determined by the rule “⅔” according to which position of Fermi level on the border metal-semiconductor is located below the bottom of conductivity band at ⅔ of width of prohibited band of the semiconductor, i.e. at ⅓ of width of prohibited band of the semiconductor above the ceiling of valence band [42]. It can be seen on FIG. 24 that the distance between the electrodes (D) is strongly exceeding the depth of penetration of the electric field, caused by contact difference of potentials, into the semiconductor (L), i.e.

$$D > L = \sqrt{\frac{2 ɛ {ɛ}_{0} {ϕ}_{k}}{en}} ,$$

where ∈—relative dielectric permeability of the semiconductor, ∈₀—the electric constant, e—charge of electron, φₖ—contact potential, n—concentration of free charge carriers in the permitted energy band (electrons in conductivity band of n-semiconductor or holes in valence band of p-semiconductor) in the state of “flat bands”. In this case, even if the coherency length Λ>D, then hyperconductivity cannot be observed by means of measuring the electric resistance of the material between the electrodes because hyperconductive electrons will dissipate on the near-contact potential barriers. I.e. the existing potential barriers having height of eφₖ are destroying the superconductive state. This unwanted effect may be eliminated by choosing D much smaller than L. The respective band energy diagram is shown on FIG. 25. It can be seen out of FIG. 25 that at D much smaller than L (D<<L) the built-in potential barrier may be lowered down to insignificant value so the height of the barrier would not exceed kT, where k—Boltzmann constant and T—absolute temperature. For this purpose, D shall be decreased. At D much smaller than L (D<<L), the semiconductor in the between-electrodes gap turns to the hole-type conductivity and is separated from the rest volume of the semiconductor by physical p-n junction and the built-in potential barriers are unable to dissipate hyperconductive electrons which may penetrate into the metal without hindrance and superconductivity may be observed by means of measuring of the electric resistance between the electrodes. At the same time, Schottky barrier prevents electrons from coming out of the metal into the inter-electrodes gap and by this eliminate their influence over hyperconductivity and superthermoconductivity.

Similar energy diagrams may be considered as well for the case of the semiconductor having hole conduction. But registration of the resistance between the electrodes is unavoidably linked to a current running through the zones of the material adjacent to the contacts and, consequently, the process of holes recombination on the border with the metal is unavoidable, which is equivalent to dissipation of holes, which is not assisting superconductivity. Besides, physical p-n junction is not forming here and mobile holes are able to move from the volume of the semiconductor into the space between the electrodes, assisting dissipation of holes and hindering appearing and existing of hyperconductivity and superthermoconductivity. Nevertheless, a material having hole type of conductivity is in principle usable for realizing of hyperconductivity and superthermoconductivity. This way, there are two conditions needed to realize hyperconductivity and superthermoconductivity in the material between the electrodes: D must be lower than A and D must be much smaller than L, (D<Λ and D<<L).

Hyperconductivity realized at temperatures above near-room temperatures by its physical mechanism is akin to the known BCS mechanism where bounding of electrons into Cooper couples is provided by virtual phonons. In our case, the bound between the electrons is provided by I-vibrations of the electron-vibration centers (EVCs) and material phonons which energies are high. Thanking to relatively high energy of I-vibration, all particles (electrons) and quasi-particles (holes, I-vibrations of atomic nucleuses, phonons) participating in this electron-vibration process (state), are able to penetrate potential barriers in the material and move in its volume without loosing or spending energy. Because of this, in the materials containing EVCs between the electrodes hyperconductivity and superthermoconductivity exists at high temperatures, above Tₕ. Exactly electrons and phonons bound to EVCs are forming the special phase of the material having its own dynamics and statistics. Hyperconductivity and superthermoconductivity, unlike traditional superconductivity, exists in the limited zone of the material, in the limits of coherency zones which are <<bound>> to poorly mobile EVCs and because of this they are deprived of possibility to quickly move inside the whole volume of the material.

Determining the value of critical magnetic field. Inductance of the critical magnetic field (B) may be estimated if we will consider frequency of phonon providing elastic bound between EVCs in materials. In silicon and other materials frequency of such phonon is close to 1.25·10¹⁰ sec⁻¹. Each EVC may be reasonably represented by the charged oscillator having effective mass m and electron charge c. The motion equation of the linear harmonic oscillator accounting acting of Lorentz force in the magnetic field having inductance B may be written the following way:

$$\frac{{d}^{2}}{d {t}^{2}} X + \frac{d}{d t} XB - m {ω}^{2} X = 0 , \qquad ( 17 )$$

where X—generalized (configuration) coordinate, ω—cyclic frequency of oscillations, B—projection of inductance of the magnetic field on the speed direction of the charge carrier. The summand containing speed

$$\frac{d}{d t} X$$

accounts action of Lorentz force, when speed

$$\frac{d}{d t} X$$

and B are mutually orthogonal. This equation permits oscillating solution under the condition

4ω²−qB/m>0. (18)

I.e. oscillation motions of I-oscillator at frequency ω are possible when B is not too strong. If frequency of the electron bound to EVC is fixed and defined by properties of electron-vibration center then, as B grows up to a certain strength, defined by the mentioned inequality, oscillations of the center will become impossible. In case the electron is participating in a complex oscillation of the center having a number of frequencies then, as B grows, the magnetic field will successively suppress oscillations having frequencies in order of their increasing. In principle, it is possible to choose such a value of B when oscillations of the electron-vibration center having any frequency will be suppressed. This is how mechanism of suppression of EVCs oscillations in the magnetic field looks like. Putting m equal to the effective mass of electron and ω=2π·1.25·10¹⁰ sec⁻¹, using this inequality we are getting the minimal value of critical inductance of the magnetic field being ≈0.25 Tesla. Intensity of the magnetic filed will take values divisible by the minimal critical intensity which corresponds to participation of one or more phonons in formation of the coherent zones. Because of this critical, maximum inductance of the magnetic field may be written down as the following formula:

$$B = S \frac{4 m {ω}^{2}}{e} ,$$

where S—constant of electron-phonon bound, m—effective mass of electron (hole), e—electron charge, ω—cyclic frequency of elastic vibration in the material related to EVCs. The value of ω may reach frequencies of I-vibration of atomic nucleuses and, respectively, critical value of B may reach hundreds and even thousands Tesla.

Regarding claim 1. The major of the described distinguishing features, important for realizing hyperconductivity and superthermoconductivity in the material between the electrodes, are given in claim 1 of the present invention, where any non-degerenerate of poorly degenerate semiconductor is used as the material; on its surface or in its volume electrodes are located forming rectifying contacts to the material, for example, joints metal-semiconductor, Schottky joints, distance between these electrodes (D) is chosen much smaller comparing to the length of penetration into the material of the electric field generated by the contact difference of potentials (L), (D<<L) and not exceeding the doubled coherency length (2Λ), (D≦2Λ); minimum distance between the electrodes D_{MIN}=10 nanometers, maximum distance between the electrodes D_{MAX}=30 micrometers; prior to, after or during forming the electrodes, electron-vibration centers (EVCs) are inputted into the material having concentration (N) from Nₘᵢₙ=2·10¹² cm⁻³ to Nₘₐₓ=6·10¹⁷ cm⁻³; heating the material up to the temperature exceeding the temperature of hyperconductivity transition (Tₕ). as the result, hyperconductivity and thermo conductivity appear in the material between the electrodes, which corresponds to the purpose of the invention.

Regarding claim 2. In order to simplify the method, EVCs may be inputted not into the whole volume of the material but only into the depleted zone of the material between the electrodes or into the parts of the depleted zone adjacent to the electrodes, because self-vibrations of atomic nucleuses in EVCs cause forced vibrations of atom nucleuses of the main material between the electrodes and by this provide conditions for hyperconductivity and superthermoconductivity to exist in the material between the electrodes. In this relation, the electron-vibration centers are inputted only into the depleted zone of the material between the electrodes or into the parts of the depleted zone which are adjacent to the electrodes, and length of the current line between the electrodes in the depleted zone is not exceeding the doubled coherency length (2Λ).

Regarding claim 3. Dimensions of the material cannot be smaller than dimensions of the coherency zone, so this zone could be housed inside the material. Because of this, the smallest size of the material gets chosen to be not smaller than the doubled coherency length (2Λ), for example, thickness of the plate of the material gets chosen not smaller than 2Λ, or thickness of the layer of the material not smaller than 2Λ on a semiconductor, semi-insulating or dielectric substrate.

Regarding claim 4. It is considered important to provide hyperconductivity and hyperthermoconductivity in the material or in a part of the material having a random form. In order to achieve this, in the said volume of the material or on the surface of the said material having dimensions strongly exceeding the doubled coherency length (2Λ) a system of electrodes is placed, for example, having forms of balls, strips or spirals. FIG. 26 shows a rectangular cross-section by plane of the researched material sample having electrodes in the form of balls. In this particular case, electrodes have no external voltages applied to them.

FIG. 26A shows the sample where the volume concentration of these electrodes 39 in the material is such so the size of the coherency zone 2Λ (38) is smaller than the average distance between these droplet-like electrodes. In this case, the coherency zones formed by these electrodes do not merge with each other and hyperconductivity exists in these separate zones of the material. The sample in this case demonstrates no macroscopic hyperconductivity, but it demonstrates interaction with an external magnetic field.

In the sample shown on FIG. 26B the volume concentration of the droplet contacts is such that their coherency zones merge with each other into the single hyperconductivity zone 40 and such sample demonstrates macroscopic hyperconductivity.

Regarding claim 5. When using electrodes of an arbitrary form, the hyperconductor may possess anisotropic physical properties. In order to eliminate anisotropy of hyperconductivity and superthermoconductivity, it is sufficient to choose the size of each electrode being much smaller comparing to the coherency length (Λ). In this case, if size of the electrode is smaller than A, then the coherency zone will embrace the electrode over all its sides and the border conditions on the surface of the coherency zone will be isotropic, which will provide isotropy of the hyperconductivity and superthermoconductivity. Because of this, a system of electrodes is put into the volume of the material, for example, in the form of droplets, or on the surface of the material, and the biggest size of each electrode gets chosen to be much smaller comparing to the coherency length Λ.

Regarding claim 6. Values of the coherency length Λ and of temperature of hyperconductivity transition Tₕ may be controlled, for example, by using external magnetic fields. Magnetic field causes suppressing effect on vibrations of charges having projections of their displacements onto the normal to the direction of the magnetic field. For complete suppression of such displacements, according to solution of equation (17), it is important to have a magnetic field of sufficient strength complying to the condition (18) which lets to use a magnetic field for adjustments of the value of Λ and, consequently, the value of Tₕ. For this purpose, a constant, alternate or impulse magnetic field is created in the material between the electrodes, directed along, normally or at a sharp angle relatively to a specific direction, for example, to the direction of current between the electrodes, having inductance of not more than

$$B = S \frac{4 m {ω}^{2}}{e} ,$$

where ω—cyclic frequency of the elastic vibration forming hyperconductive state and S—constant of bound of this vibration with electrons.

Action of the magnetic field and size of the coherency zone along a particular direction appears not the same for transversal and longitudinal vibrations. Because of this, depending on structure of the center interacting primarily with longitudinal or primarily with transversal phonons, the magnetic field may cause increasing or decreasing of Λ along particular directions in the material, increasing or decreasing full energy of the coherency zone. In this relation, the material having electrodes is wither pulled into the magnetic field or pushed out of the magnetic field as do, for example, the silicon samples having A-centers, demonstrating the effect similar to Meissner effect in superconductors.

Regarding claim 7. A technical possibility exists to control the coherency length Λ and the temperature of hyperconductivity transition Tₕ by means of an external illumination of the material between the electrodes. For this purpose, the material between the electrodes is illuminated in the spectrum band of self, inherent, fundamental absorption by the material and (or) in the spectrum band of absorption by EVCs with intensity up to

$$I = \frac{{N}_{C}}{ϛ τ} ,$$

where N_{C}—effective number of electron states in the permitted energy band, ζ—coefficient of optical absorption and τ—lifetime of electrons (holes).

Illumination of the material between the electrodes produces additional concentrations of charge carriers not exceeding N_{C}, which affect concentration of active EVCs. Besides, illumination directly affects concentration of active EVCs and oscillation energy of these centers E_{osc} and, in accordance with formula (16), cause changes of Λ and respective changes of Tₕ. This is the basis for technical control of the values Λ and Tₕ suggested for use by claim 7.

Regarding claim 8. A technical possibility exists to control the coherency length Λ and the temperature of hyperconductivity transition Tₕ by means of temperature difference of the electrodes. In this case, thermodynamic equilibrium gets violated in the material between the electrodes, temperatures of different parts of the material change, which causes changes in the coherency length, in the size of the coherency zones and, consequently, in the temperature of the hyperconductivity transition. There is no need to establish the temperature difference (ΔT) between the electrodes to be more than Sω/k when energies of EVCs near these electrodes differ in the sum of energies of average number of phonons (S) participating in electron-vibration transitions. In this relation, a temperature difference is created between the electrodes not exceeding the value of ΔT=Sω/k, where S—constant of bound between electrons and phonons, —Planck constant, k—Boltzmann constant, ω—cyclic frequency of the phonon defining the elastic bound between EVCs in the material between the electrodes.

Regarding claim 9. In order to control the values of Λ and Tₕ, it is possible to use an additional electrode forming a rectifying contact or contact metal-insulator-semiconductor (MIS) to the material between the electrodes, or a number of such electrodes. Constant, alternate or impulse external voltages having direct or reverse polarities are applied to the additional electrodes relatively to the material. The voltages applied to the additional electrodes cause injection of electrons into the material affecting the state of depletion of the material and, by this, are causing changes in concentration (N) of electrically active EVCs and of the vibration energy E_{osc}. As the result, changes appear in the values of Λ and Tₕ.

Values of the voltages applied to the additional electrodes are defined by commonly known requirements providing integrity, stability and longevity of these contacts.

Regarding claim 10. It is possible to control values of the coherency length Λ and of the temperature of hyperconductivity transition Tₕ by creating, applying an alternate or constant difference of potentials between the electrodes having value of up to Sω/e, where S—constant of electron-phonon bound, —Planck constant, ω—cyclic frequency of elastic vibrations in the material, for example, frequency of phonon or of I-oscillations in atomic nucleuses of the material.

Difference of the electric potentials between the electrodes produces the difference of the potential energies of EVCs in different parts of the material between the electrodes and changing of the number of active EVCs and of the oscillation energy E_{osc} which causes changing of the coherency length Λ and of the temperature of hyperconductivity transition Tₕ.

Regarding claim 11. The coherency length Λ and the temperature of hyperconductivity transition Tₕ may be controlled by sending into the material between the electrodes of a flow of sound, ultrasound or hyper sound. Actually, the elastic vibrations of the material participate in the electron-vibration transitions. Changing concentration of quanta of such elastic vibrations like sound, ultrasound, hyper sound differing only by frequency f, affects the speed of electron-vibration transitions, the vibration energy (E_{osc}), the coherency length Λ and the temperature of hyperconductivity transition Tₕ. Power of the sonic, ultrasonic or hypersonic flow directed into a single volume of the material between the electrodes may be determined the following way, taking into account that on average S quanta of any of such waves (vibrations) participate in each electron-vibration transition. Cyclic frequency of quant of elastic vibration is 2πf and its energy is 2πf. Energy of quanta of such elastic waves in a single volume of the material 2πfN is spent during the lifetime of electrons (holes) τ. Because of this, the volume energy of the sound, ultrasound or hyper sound flow directed into the material between the electrodes may reach (2πSfN)/τ. Efficiency of the effect caused by the sound, ultrasound or hyper sound on the values of Λ and Tₕ depends on direction of these flows relatively to the borders of the material or of a substrate. Direction of these waves normally to the border of the material or a substrate provides lower losses of the power due to reflection and creates additional conditions for increasing the probability of their absorption in the material due to their numerous reflections from the flat-parallel borders of the material or of a substrate, and their numerous passing through the volume of the material.

Regarding claim 12. It is possible to stabilize hyperconductivity and superthermoconductivity in the material between the electrodes by choosing thickness of the semiconductor plate or thickness of the semiconductor layer on a substrate, or thickness of the substrate, or joint thickness of the semiconductor layer and the substrate, or the distance (distances) between mutually parallel edges of the semiconductor being equal to or multiply by W=ν/2f, where ν—speed of sound (phonon) having frequency f, propagating between the mutually parallel edges of the semiconductor, the substrate or both the semiconductor and the substrate, f—frequency of the phonon defining the elastic bound between EVCs.

In case of fulfilling of this condition, known as the condition of acousto-electric synchronism, phonons, reflected from the edges and surfaces of the material, return back into the material between the electrodes. By means of this, concentration of phonons sufficient for—providing hyperconductivity and superthermoconductivity is provided.

Regarding claim 13. It is possible to stabilize hyperconductivity and superthermoconductivity in the material between the electrodes by choosing thickness of the semiconductor plate or thickness of the semiconductor layer on a substrate, or thickness of the substrate, or joint thickness of the semiconductor layer and the substrate, or the distance (distances) between mutually parallel edges of the semiconductor being equal to or multiply by W=ν/2f, where ν—speed of sound propagating between the mutually parallel edges of the semiconductor, the substrate or both the semiconductor and the substrate, f=1/P, where P—period of the alternate electric or magnetic field generated in the material between the electrodes. Such stabilization is reached by means of acousto-electric synchronism returning the sound (phonons) from other parts of the material into the material between the electrodes.

Application of the present invention will provide a significant scientific, technical and economical effect by means of using hyperconductivity and superthermoconductivity in technology, devices and systems.

List of figures. The invention is illustrated by the drawings.

FIG. 1 shows the material (semiconductor) having the electrodes 1 and 2 on its surface or in its volume.

FIG. 2, bottom part, shows the dispersion curves accounting interaction of I-vibrations of atomic nucleuses with acoustic vibrations of atoms at δ>0 and δ<0. In the top part, a single-dimensional adiabatic model of the material, crystal having constant a is shown.

On FIG. 3 white circles show the calculated values of elementary quant of I-vibrations of α, β and γ types in atoms having various atomic numbers Z. Dark circles show the experimental values of quanta for certain atoms.

FIG. 4 graphically shows corrections to the energies of α-type vibrations of atomic nucleuses (ΔE_{αv}) in the states having oscillation quantum numbers v=0, 1, 2, 3 depending on atomic number Z, calculated in the first and the second orders of the perturbation theory. In the insert to this figure these corrections are shown in the other scale for atoms hiving Z>10.

FIG. 5 shows the energy diagram of the hyperconductor.

On FIG. 6 solid line shows the temperature dependence of the electric resistance (R) of the hyperconductor, calculated using the BCS theory accounting I-vibrations of atomic nucleuses. Dotted line relates to the possible transition of the material into superconductive state at low temperatures.

On FIG. 7 experimental points show the experimental dependences of temperatures of hyperconductivity transition Tₕ for materials depending on the average value of atomic number Zₐᵥᵣ. The inclined lines a and b correspond to the calculated values of Tₕ at minimal (N_{MIN}) and maximal (N_{MAX}) concentrations of EVCs.

FIG. 8 shows the cross-section of the material sample having electrodes 1 and 2 by the plane (XY) running through the center of the coherency zone. The dotted circle with radius Λ corresponds to the border of the coherency zone, lₑ—length of electron free run.

FIG. 9 shows data of thickness of the dielectric layer (d) through which electrons are tunneling at changing of CV characteristics of the semiconductor structures depending on concentration (N) of the electron-vibration centers.

FIG. 10 shows data regarding height of the potential barrier depending on thickness of the dielectric layer (d) through which electrons are tunneling in the structure metal-semiconductor oxide-semiconductor, derived out of volt-farad (CV) measurements.

FIG. 11 shows the temperature dependences of specific resistance of monocrystal GaP without dopings (curve 3) and containing electron-vibration centers formed by doping atoms of aluminum (curve 4) and Sulfur (curve 5).

FIG. 12 shows spectrum of changing of IR reflection coefficient (dR) caused by doping atoms of aluminum in GaP. The experimental curve 6 is a sum of curves 7, 8, 9, 10 representing shares into the reflection of I-oscillators of aluminum atoms in various oscillation states having v=0, 1, 2, 3.

FIG. 13 shows the temperature dependence of thermo-EMF of GaP monocrystal doped with sulfur atoms (curve 11) and not doped GaP (curve 12).

FIG. 14 shows the photoconductivity spectrums (a), curve 13, and the spectrum of optical passing through (P), curve 14, of monocrystal silicon containing A-centers in concentration of≈10¹⁴ cm⁻³. The insert shows the experimental data on changing frequencies of acoustic and optical phonons of silicon, caused by changing of A-centers concentration in the material.

FIG. 15 shows typical temperature dependences of thermo-EMF E(T) for the silicon samples doped with atoms of phosphorous and oxygen, curve 15, and for porous silicon on silicon substrate, curve 16.

FIG. 16 shows volt-farad (CV) characteristics of contacts Al—Si, curves 17-22, measured on the following frequencies: 0.2 MHz, 0.5 MHz, 1 MHz, 5 MHz, 10 MHz, 20 MHz.

FIG. 17 shows typical temperature dependences of specific resistance of the silicon between the electrodes, curves 23-26, having the respective various distances between the electrodes D: 50 mkm, 40 mkm, 30 mkm, 22 mkm.

FIG. 18 shows cross-section of the researched sample having electrodes 1 and 2 divided by the distance D>2Λ between them, by a plane running through the center of the coherency zone.

FIG. 19 shows typical temperature dependences of resistance of the silicon between the electrodes divided by the gap D<2Λ, curves 27 and 28.

FIG. 20 shows typical temperature dependences of resistance of germanium, curve 29, and Silicon, curve 30, between the electrodes divided by the gap D=19 mkm<2Λ.

FIG. 21 shows typical temperature dependences of resistance of CdHgTe monocrystals, curve 31, and InSb, curve 32, between the electrodes divided by the gap D<2Λ. Insert shows typical temperature dependences of resistance of germanium, curve 33, and silicon, curve 34, between the electrodes divided by the gap D<2Λ.

FIG. 22 shows typical temperature dependence of thermo-EMF of silicon, curve 35, between the electrodes divided by the gap D=19 mkm.

FIG. 23 shows typical temperature dependences of resistance, curve 36, and thermo-EMF, curve 37, of Silicon between the electrodes divided by the gap of D<2Λ.

FIG. 24 shows the zone energy diagram of the material between the electrodes divided by the gap D exceeding the length of penetration of the electric field cause by the contact difference of potentials into the material L, (D>L).

FIG. 25 shows the zone energy diagram of the material between the electrodes divided by the gap D being smaller comparing to the length of penetration of the electric field caused by contact difference of potentials into the material L, (D<L).

FIGS. 26A and 26B shows sectional view of the material containing electrodes as droplets.

### BIBLIOGRAPHY

1. Onnes H. K., Leiden. Comm., 1911, p. 120b, 122b.
2. Tinkham M., Introduction to superconductivity. Moscow, Atomizdat, 1980.
3. Problem of high temperature superconductivity, under the editorship of V. L. Ginzburg and D. A. Kirzhnits. Moscow., Nauka, 1977, p. 400.
4. Ginzburg V. L., Maksimov E. G. About possible mechanisms of high temperature superconductivity. Superconductivity. Physics, chemistry, technology. 1992, t. 5, No. 9, pp. 1543-1596.
5. A. M. Gulian, K. S. Wood, D. Van. Vechten, J. Classen, R. J. Soulen, Jr, S. Qadry, M. Osovsky, A. Lucarelly, G. Lüpke, R. G. Badalian, V. S. Kuzanyan, A. S. Kuzanyan, V. R. Nicoghosyan. Evidence for high temperature superconductivity in doped laser processed Sr—Ru—O].
6. http://www.superconductors.org/212K.htm; E. Joe Eck© 2008 Superconductors.ORG Patent No. 61/199,804.
7. Bardeen J., Cooper L. N., Schrieffer J. R. Phys. Rev., v.108, 1957, p. 1175.
8. W. A. Little, Phys. Rev. A134, p. 1416, 1964.
9. V. L. Ginzburg, Phys. Lett. 13, p. 101, 1964; ZhETF 47, p. 2318, 1964.
10. V. A. Vdovenkov. A new type of elastic vibrations and waves in crystals. Collection of scientific works of the Moscow Institute of Radiotechnics, Electronics and Automatics. “Radio-electronic devices and systems for signal processing”, 1996, pp. 148-150.
11. V. A. Vdovenkov. Superconductivity defined by electron-vibration centers—hyperconductivity. Inter-industry collection of scientific works of MIREA “Thermo vision” pp. 33-39, Moscow, 2000.
12. V. A.Vdovenkov. Superconductivity at very high temperatures—hyperconductivity. Arxiv: cond-mat/0003190; arxiv:cond-mat\0207215.
13. V. A. Vdovenkov. Researches of local thermo-EMF and hyperconductivity. High technology, No 4, 2002, v. 3, pp. 55-60.
14. V. A. Vdovenkov. Electron-vibration centers in semiconductor components of microsystems technology. Microsystems technology, No. 12, Moscow, 2002, pp. 17-22.
15. V. A. Vdovenkov. Phonon-Drag Thermo-power at High Temperatures. arxiv:cond-mat/9904299; arXiv:cond-mat\0207218.
16. M. Born, R. Oppenheimer. Ann. D. Phys. v. 84, N4, 1927, p. 457.
17. D. R. Hartree. Proc. Cambr. Phil. Soc. v. 24, 1928, p. 111.
18. V.Fock. Z. Phys., v. 62, 1930, p. 126; v. 62, 1930, p. 795.
19. A. S. Davydov. Quantum mechanics. Moscow., Nauka, 1973, p. 613.
20. A. M. Stoneham. Theory of defects in solids. Moscow., Mir, 1978, t. 1, p. 48. (A. M. Stoneham/Theory of defects in solids. Clarendon Press. Oxford 1975).
21. V. A. Vdovenkov. Adiabatic and non-adiabatic electronics of materials. Materials of the International Scientific Conference <<Thin films and nanostructures>>, 2005, Moscow, part 2, pp. 99-104; the same: ArXiv:cond-mat\0610828.
22. Z. Flugge. Tasks of quantum mechanics. Moscow., Mir, 1974, t. 1, p. 93. (Sigfried Fltigge. Practical Quantum Mechanics I. Springer-Verlag, 1971).
23. Pekar S. I. Researches in electron theory of crystals.—M., Gostechizdat, 1951. p. 204.
24. Huang K. and Rhys A. Proc. Roy. Soc. 1950. V. A204. P. 406.
25. Pekar S. I. ZhETF. 1952. t. 22, issue. 6, p. 641.
26. Pekar S. I. UFN. 1953. T. L, issue. 2, p. 197.
27. Stocker J. Non-linear oscillations in mechanical and electric systems.-Moscow: International Literature, 1953. p. 15-22, p. 183-210.
28. V. A. Vdovenkov. Electrons drag by phonons defined by electron-vibration transition in materials. Izvestiya VUZov, Materials of Electronic Technology, No. 1, 2005, p. 65-70.
29. Stilbans. Physics of semiconductors.—Moscow.: Soviet Radio, 1963. p. 299-304.
30. V. A. Vdovenkov. Tunneling of electrons in MOS-structures. Collection of scientific works of MIREA <<Informatics and radio-technology>>, 1995, pp. 41-43.
31. K. V. Shalimova. Physics of semiconductors.—Moscow: Energy, 1976, p. 416.
32. R. Marshall, S. S. Mitra. Phys. Rev., v. 134, A1019, (1964).
33. L.Rosenfeld. Theory of Electrons. Norh Holland, Amsterdum, (1951).
34. P. Noziers, D. Pines. Phys.Rev., v. 109, p. 741, (1958).
35. D. A.Kleinman, W,G,Spitzer. Phys.Rev. v. 118, p. 100, (1960).
36. G.Bemsky. J. Appl. Phys., 1959, v. 30, p. 1127.
37. Vavilov V. S., Plotnikov A. F., Akimchenko I. P., Vdovenkov V. A. Oscillations in spectrums of photoconductivity and absorption linked to A-center in silicon. FTT, 1968, t. 10, pp. 3677-3678.
38. J. E.Aubrey, W.Gubbler, T.Henningsen, S. H.Koenig. Phys. Rev. v. 130, N5, p. 1667 (1963).
39. Hone J., Ellwood I., Muto M., Mizel A., Cohen M. L., Zettl A., Rinzler A. G., Smally R. E.//Phys. Rev. Lett. 1998. V. 80, No 5, p. 1042.
40. V. A. Vdovenkov. Author's certificate of USSR No. 1570571; A/c of USSR No. 1823704.
41. V. A. Vdovenkov. Specifics of semiconductor structures of microelectronics having centers of Jahn-Teller. Technika Sredstv Svyazi, series LOSS, issue 2, pp. 14-19. Moscow., 1990.
42. S. Zi. Physics of semiconductor devices. Mir, Moscow, 1984, t. 1, p. 283.

1. Method for realization of hyperconductivity and superthermoconductivity in a material between the electrodes comprising a condensed material having particular chemical content, and technological treatments of the material, as well the electrodes forming the electric contacts to the material, characterized in that any non-degenerate or poorly degenerate semiconductor is used as the said material; on the surface or in the volume of the said material the electrodes are located forming rectifying contacts to the said material, for example, contacts metal-semiconductor, Schottky joints; the distance between the said electrodes (D) is chosen much smaller comparing to the length of penetration into the said material of the electric field caused by the contact difference of potentials (L) (D<<L) and not exceeding the doubled coherency length (2Λ) (D≦2Λ); the minimum distance between the said electrodes D_{MIN}=10 nanometers, the maximum distance between the said electrodes D_{MAX}=30 micrometers; prior to, after, or during forming of the said electrodes, electron-vibration centers (EVCs) are inputted into the material having concentration (N) from Nₘᵢₙ=2·10¹² can to Nₘₐₓ=6·10¹⁷ cm⁻³; the said material is heated up to a temperature exceeding the temperature of hyperconductivity transition (Tₕ).

2. Method for realization of hyperconductivity and superthermoconductivity in the material between the electrodes according to claim 1, characterized in that the said electron-vibration centers are inputted into the depleted zone of the said material between the said electrodes or into the parts of the depleted zone adjacent to the said electrodes, and the length of the electric current line between the said electrodes in the said depleted zone or the said parts of the said depleted zone is not exceeding the doubled coherency length (2Λ).

3. Method for realization of hyperconductivity and superthermoconductivity in the material between the electrodes according to claim 2, characterized in that the smallest size of the said semiconductor material is chosen to be not smaller than the doubled coherency length 2Λ, for example thickness of the plate of the said material is chosen not smaller than 2Λ, or thickness of the layer of the said material not smaller than 2Λ on the semiconductor, semi insulating or dielectric substrate.

4. Method for realization of hyperconductivity and superthermoconductivity in the material between the electrodes according to claim 3 characterized in that in the volume of the said material or on the surface of the said material having dimensions strongly exceeding the double coherency length (2Λ) a system of electrodes is located, for example having forms of balls, strips or spirals.

5. Method for realization of hyperconductivity and superthermoconductivity in the material between the electrodes according to claim 4, characterized in that a system of electrodes is located in the volume or on the surface of the said material, for example, in the form of droplets, and the largest dimension of each of these electrodes is chosen to be much smaller comparing to the said coherency length Λ.

6. Method for realization of hyperconductivity and superthermoconductivity in the material between the electrodes according to claim 5 characterized in that in the said material between the said electrodes a constant, variable or impulse magnetic field is created directed along, normal or under a sharp angle to a particular direction, for example, to the direction of current between the said electrodes having inductance not exceeding
$$B = S \frac{4 m {ω}^{2}}{e} ,$$
Where ω—cyclic frequency of the elastic vibration forming the hyperconductive state, S—constant of bound between the said vibration and electrons, m—effective mass of electron (hole) and e—charge of electron.

7. Method for realization of hyperconductivity and superthermoconductivity in the material between the electrodes according to claim 1 characterized in that the said material between the said electrodes is illuminated in the spectrum band of self, inherent, fundamental absorption by the said material and (or) in the spectrum band of absorption by EVCs having the intensity of up to
$$I = \frac{{N}_{C}}{ϛ τ} ,$$
where N_{C}—effective number of electron states in the permitted energy band, ζ—coefficient of optical absorption and τ—lifetime of electrons (holes).

8. Method for realization of hyperconductivity and superthermoconductivity in the material between the electrodes according to claim 6 characterized in that between the said electrodes the temperature difference is created not exceeding ΔT=Sω/k, where S—constant of bound between electrons and phonons, —Planck constant, k—Boltzmann constant, ω—cyclic frequency of phonon defining the elastic bound between EVCs in the said material between the said electrodes.

9. Method for realization of hyperconductivity and superthermoconductivity in the material between the electrodes according to claim 8 characterized in that an additional electrode is used forming a rectifying contact or contact metal-dielectric-semiconductor (MDS) to the said material between the said electrodes, or a number of such additional electrodes are used; constant, variable or impulse external voltages having direct or reverse polarities relatively to the said material are applied to these additional electrode or electrodes.

10. Method for realization of hyperconductivity and superthermoconductivity in the material between the electrodes according to claim 9 characterized in that between the said electrodes a variable or constant difference of electric potentials is created having the value of up to Sω/e, where S—constant of electron-phonon bound, —Planck constant, ω—cyclic frequency of elastic vibrations of the material, for example, the frequency of phonon or the frequency of I-oscillations of nucleus in atoms of the said material, e—charge of electron.

11. Method for realization of hyperconductivity and superthermoconductivity in the material between the electrodes according to claim 10 characterized in that a flow of sound, ultrasound or hyper sound having frequency f and volume energy density (2πSfN)/τ is directed into the material between the electrodes, where S—constant of electron-phonon bound, N—concentration of EVCs, τ—lifetime of electrons (holes) in the said material between the said electrodes, —Planck constant.

12. Method for realization of hyperconductivity and superthermoconductivity in the material between the electrodes according to claim 1 characterized in that thickness of the semiconductor plate, or thickness of the semiconductor layer on a substrate, or thickness of the substrate, or joint thickness of the semiconductor layer and the substrate, or distance (distances) between mutually parallel edges of the said semiconductor are chosen to be equal to or multiply by W=ν/2f, where ν—speed of the sound (phonon) having frequency f, propagating between the said mutually parallel limits of the said semiconductor, the said substrate, the said semiconductor and the said substrate, f—frequency of the phonon defining the elastic bound between EVCs.

13. Method for realization of hyperconductivity and superthermoconductivity in the material between the electrodes according to claim 1 characterized in that thickness of the semiconductor plate, or thickness of the semiconductor layer on a substrate, or thickness of the substrate, or joint thickness of the semiconductor layer and the substrate, or distance (distances) between mutually parallel edges of the said semiconductor are chosen to be equal to or multiply by W=ν/2f, where ν—speed of sound propagating between the named mutually parallel limits of the said semiconductor, the said substrate or the said semiconductor and the said substrate, f=1/P, where P—period of alternate electric or magnetic field created in the said material between the said electrodes.
